(19) United States
(12) Patent Application Publication
(10) Pub. No.: US 2024/0231215 A9
(43) Pub. Date: Jul. 11, 2024

(54) REFLECTION TYPE MASK BLANK AND METHOD FOR MANUFACTURING SAME

(71) Applicant: AGC Inc., Tokyo (JP)

(72) Inventors: Wataru NISHIDA, Tokyo (JP); Masaru HORI, Aichi (JP); Takayoshi TSUTSUMI, Aichi (JP)

(73) Assignee: AGC Inc., Tokyo (JP)

(21) Appl. No.: 18/403,811

(22) Filed: Jan. 4, 2024

Related U.S. Application Data
(63) Continuation of application No. PCT/JP2022/026816, filed on Jul. 6, 2022.

(30) Foreign Application Priority Data
Jul. 12, 2021 (JP) 2021-114867
Jan. 6, 2022 (JP) 2022-000942

(51) Int. Cl. G03F 1/24

(52) U.S. Cl. CPC G03F 1/24

(57) ABSTRACT

A reflective mask blank includes: a substrate; a Mo/Si multilayer reflection layer formed by alternately laminating a molybdenum (Mo) layer and a silicon (Si) layer on or above the substrate; an intermediate layer on or above the Mo/Si multilayer reflection layer; a barrier layer on or above the intermediate layer; a protective layer on or above the barrier layer; and an absorption layer on or above the protective layer.

### CROSS-REFERENCE TO RELATED APPLICATIONS

This is a bypass continuation of International Patent Application No. PCT/JP2022/026816, filed on Jul. 6, 2022, which claims priority to Japanese Patent Application No. 2021-114867, filed on Jul. 12, 2021 and Japanese Patent Application No. 2022-000942, filed on Jan. 6, 2022. The contents of these applications are hereby incorporated by reference in their entireties.

### TECHNICAL FIELD

The present invention relates to a reflective mask blank and a method for manufacturing the same.

### BACKGROUND ART

In recent years, with the miniaturization of integrated circuits that constitute semiconductor devices, extreme ultra violet (hereinafter referred to as “EUV”) lithography has been studied as an exposure method that can replace exposure techniques using a visible light, an ultra violet (wavelength: 193 nm to 365 nm), an ArF excimer laser light (wavelength: 193 nm), or the like in the related art.

In the EUV lithography, EUV light having a wavelength shorter than that of the ArF excimer laser light is used as a light source for exposure. EUV light refers to light having a wavelength in a soft X-ray region or a vacuum ultraviolet region, specifically light having a wavelength of about 0.2 nm to 100 nm. As the EUV light, a EUV light having a wavelength of, for example, about 13.5 nm is used.

Since the EUV light is easily absorbed by various substances, a refractive optical system used in the exposure techniques in the related art cannot be used. Therefore, in the EUV lithography, a reflective optical system such as a reflective mask and a mirror is used. In the EUV lithography, a reflective mask is used as a transfer mask.

A mask blank is a pre-patterning laminate used for manufacture of photomasks. A reflective mask blank has a structure in which a reflection layer that reflects the EUV light and an absorption layer that absorbs the EUV light are formed in this order on or above a substrate made of glass or the like.

As the reflection layer, a multilayer reflection layer, whose light reflectance is increased during irradiation of a layer surface with the EUV light by alternately laminating a low-refractive-index layer having a low refractive index with respect to the EUV light and a high-refractive-index layer having a high refractive index with respect to the EUV light, is generally used. A molybdenum (Mo) layer is generally used as the low-refractive-index layer of the multilayer reflection layer, and a silicon (Si) layer is generally used as the high-refractive-index layer of the multilayer reflection layer.

For the absorption layer, a material having a high absorption coefficient for the EUV light, specifically, for example, a material containing chromium (Cr) or tantalum (Ta) as a main component is used.

On the other hand, an environment in an EUV exposure machine is severe with respect to the reflective optical system, a reflection characteristic is lowered, and service life is reduced. Therefore, in order to extend the life of the reflective optical system and prevent a decrease in reflectance, hydrogen is used for an atmospheric gas in the EUV exposure machine. Since hydrogen has relatively low absorption with respect to the EUV light having a wavelength of 13.5 nm, hydrogen is more preferable than other candidates of the atmosphere gas in the EUV exposure machine such as He and Ar exhibiting higher absorption.

However, a use of hydrogen may adversely affect the multilayer reflection layer constituting the reflective mask. Since atomic hydrogen dissociated by the EUV light is very small, it is considered that atomic hydrogen easily diffuses deeply into several layers of the multilayer reflection layer constituting the reflective mask.

In the case where atomic hydrogen diffuses into the multilayer reflection layer, atomic hydrogen bonds to Si, which is one of constituent materials of the multilayer reflection layer, and is captured within the multilayer reflection layer, at an interface, or both. This phenomenon depends on a hydrogen flux to a surface of the reflective mask, a hydrogen dose absorbed by the reflective mask, and a concentration of hydrogen in these regions. In the case where the hydrogen concentration is higher than a certain threshold, bubbles of a gaseous hydrogen compound may be formed. In the case where the bubbles of the hydrogen compound are actually formed, a gas pressure inside the bubbles deforms a layer above the bubbles, leading to formation of a blister on the multilayer reflection layer. Further growth of the bubbles may cause the blister to burst, resulting in peeling of the multilayer reflection layer (Patent Literatures 1 and 2).

It is disclosed that in an extreme ultraviolet ray photomask described in Patent Literature 3, by providing a hydrogen absorption layer between a multilayer reflection layer and a capping layer on the multilayer reflection layer, it is possible to prevent formation of a blister on the photomask.
Patent Literature 1: WO2015/117887
Patent Literature 2: WO2017/123323
Patent Literature 3: JP2019-113825A

### SUMMARY OF INVENTION

However, Patent Literature 3 describes that in the extreme ultraviolet ray photomask, a metal silicide layer is formed between the multilayer reflection layer and the hydrogen absorption layer (paragraph 0051). The metal silicide layer is formed by mixing Si of the multilayer reflection layer and a metal contained in the hydrogen absorption layer. In the case where the mixing of Si of the multilayer reflection layer and a component element of a functional layer provided on or above the multilayer reflection layer progresses, reflectance at the time of irradiation with EUV light decreases (see paragraph 0006 and the like of JP2005-268750A).

Hereinafter, in the present specification, the mixing of Si of the multilayer reflection layer and the component element of the functional layer provided on or above the multilayer reflection layer will be described as “mixing on or above a multilayer reflection layer”. Further, the decrease in reflectance at the time of the irradiation with the EUV light is described as “decrease in reflectance for EUV light”.

An object of the present invention is to provide a reflective mask blank capable of preventing an occurrence of a blister in a multilayer reflection layer and preventing a decrease in reflectance for EUV light due to the mixing on or above the multilayer reflection layer during a use of a reflective mask under a hydrogen atmosphere.

As a result of intensive studies, the present inventors have found that the above problems can be solved by the following configuration.
[1] A reflective mask blank including:
a substrate;
a Mo/Si multilayer reflection layer formed by alternately laminating a molybdenum (Mo) layer and a silicon (Si) layer on or above the substrate;
an intermediate layer on or above the Mo/Si multilayer reflection layer;
a barrier layer on or above the intermediate layer;
a protective layer on or above the barrier layer; and
an absorption layer on or above the protective layer.
[2] The reflective mask blank according to [1], in which
the barrier layer contains at least one element selected from the group consisting of tantalum (Ta) and niobium (Nb).
[3] The reflective mask blank according to [2], in which
the barrier layer further contains at least one element selected from the group consisting of ruthenium (Ru), rhodium (Rh), Si, Mo, and zirconium (Zr).
[4] The reflective mask blank according to [2] or [3], in which
the barrier layer further contains at least one element selected from the group consisting of nitrogen (N), oxygen (O), and boron (B).
[5] The reflective mask blank according to [1], in which
the barrier layer contains at least one selected from the group consisting of boron carbide (B₄C) and yttrium nitride (YN).
[6] The reflective mask blank according to any one of [1] to [5], in which
the intermediate layer contains at least silicon (Si) and nitrogen (N).
[7] The reflective mask blank according to [6], in which
the intermediate layer contains 75 at % to 99.5 at % of Si and 0.5 at % to 25 at % of N.
[8] The reflective mask blank according to any one of [1] to [7], in which
the protective layer contains at least one element selected from the group consisting of Ru and Rh.
[9] The reflective mask blank according to any one of [1] to [8], in which
the barrier layer has a film thickness of 0.5 nm to 2.5 nm.
[10] The reflective mask blank according to any one of [1] to [9], in which
the intermediate layer has a film thickness of 0.1 nm to 2.4 nm.
[11] The reflective mask blank according to any one of [1] to [10], in which
the protective layer has a film thickness of 1 nm to 10 nm.
[12] The reflective mask blank according to any one of [1] to [11], further including, on or above the absorption layer, an antireflection layer with respect to an inspection light used for a mask pattern inspection.
[13] A method for manufacturing the reflective mask blank according to any one of [1] to [11], the method including:
forming the Mo/Si multilayer reflection layer on or above the substrate;
forming the intermediate layer on or above the Mo/Si multilayer reflection layer;
forming the barrier layer on or above the intermediate layer;
forming the protective layer on or above the barrier layer; and
forming the absorption layer on or above the protective layer.
[14] The method according to [13], in which
the Mo/Si multilayer reflection layer, the barrier layer, and the protective layer are formed by a sputtering method, and
the steps of forming the Mo/Si multilayer reflection layer, forming the intermediate layer, forming the barrier layer, and forming the protective layer are continuously performed in a same film forming chamber.

According to the present invention, it is possible to provide a reflective mask blank capable of preventing an occurrence of a blister in a multilayer reflection layer and preventing a decrease in reflectance for EUV light due to the mixing on or above the multilayer reflection layer during a use of a reflective mask under a hydrogen atmosphere.

### BRIEF DESCRIPTION OF DRAWINGS

FIG. 1 is a schematic cross-sectional view showing an embodiment of a reflective mask blank of the present invention.

FIG. 2 is a schematic cross-sectional view showing another embodiment of a reflective mask blank of the present invention.

FIG. 3 is a schematic cross-sectional view showing an embodiment of a reflective mask of the present invention.

FIG. 4 is a view showing a procedure for forming a pattern on a reflective mask blank 1a shown in FIG. 1. A resist film 30 is formed on an absorption layer 16 of the reflective mask blank 1a.

FIG. 5 is a view showing a procedure following FIG. 4. A resist pattern 300 is formed on the resist film 30.

FIG. 6 is a view showing a procedure following FIG. 5. An absorption layer pattern 160 is formed in the absorption layer 16.

FIG. 7 is a schematic view showing a hydrogen irradiation test sample used in Examples.

FIGS. 8A and 8B show observation images by a scanning electron microscope of a test sample in Example 1 after hydrogen irradiation. FIG. 8A is an observation image of a sample surface, and FIG. 8B is an observation image of a sample cross section.

FIGS. 9A and 9B show observation images observed by a scanning electron microscope of a test sample in Example 2 after hydrogen irradiation. FIG. 9A is an observation image of a sample surface, and FIG. 9B is an observation image of a sample cross section.

FIGS. 10A and 10B show diagrams showing results of an ion diffusion simulation in the test samples after the hydrogen irradiation. FIG. 10A shows a result of the sample in Example 1, and FIG. 10B shows a result of the sample in Example 2.

FIGS. 11A to 11G are diagrams showing results of an ion diffusion simulation in test samples after hydrogen irradiation. FIG. 11A shows a result in the case where a barrier layer 240 is a B₄C layer having a film thickness of 2.5 nm, FIG. 11B shows a result in the case where the barrier layer 240 is a TaN layer having a film thickness of 2.5 nm, FIG. 11C shows a result in the case where the barrier layer 240 is a TaB₂ layer having a film thickness of 2.5 nm, FIG. 11D shows a result in the case where the barrier layer 240 is a Nb layer having a film thickness of 2.5 nm, FIG. 11E shows a result in the case where the barrier layer 240 is a NbN layer having a film thickness of 2.5 nm, FIG. 11F shows a result in the case where the barrier layer 240 is a NbB₂ layer having a film thickness of 2.5 nm, and FIG. 11G shows a result in the case where the barrier layer 240 is a YN layer having a film thickness of 2.5 nm.

FIGS. 12A to 12D shows surface observation images observed by a scanning electron microscope of test samples after hydrogen irradiation. FIG. 12A is an observation image of a sample in Example 3, FIG. 12B is an observation image of a sample in Example 4, FIG. 12C is an observation image of a sample in Example 5, and FIG. 12D is an observation image of a sample in Example 6.

FIG. 13 is a schematic view showing a sample prepared in Example 7.

### DESCRIPTION OF EMBODIMENTS

Hereinafter, a reflective mask blank according to the present embodiment will be described with reference to the drawings.

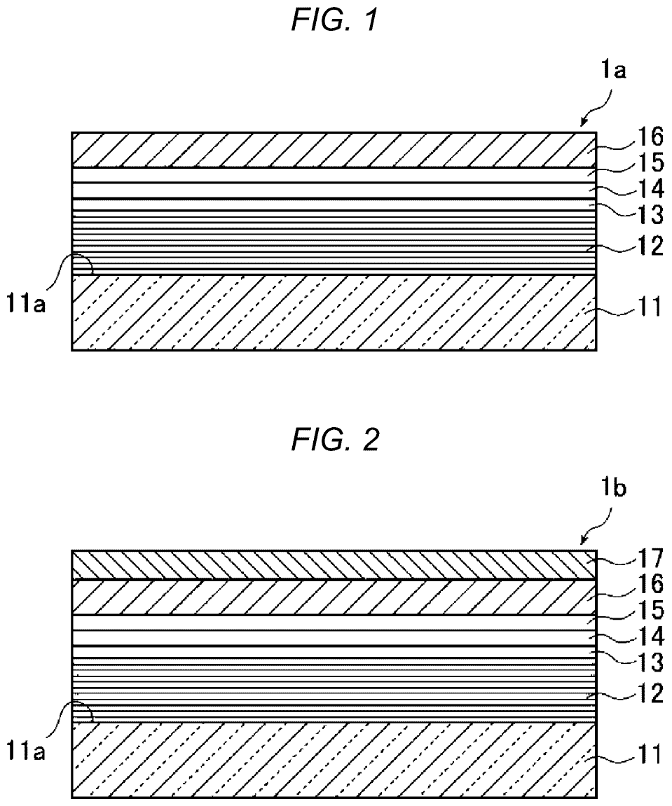

FIG. 1 is a schematic cross-sectional view showing an embodiment of a reflective mask blank of the present invention. A reflective mask blank 1a shown in FIG. 1 includes a substrate 11, a Mo/Si multilayer reflection layer 12 on the substrate 11, an intermediate layer 13 on the Mo/Si multilayer reflection layer 12, a barrier layer 14 on the intermediate layer 13, a protective layer 15 on the barrier layer 14, and an absorption layer 16 on the protective layer 15.

The substrate 11 preferably has a small thermal expansion coefficient. As the thermal expansion coefficient of the substrate 11 is small, distortion in a pattern formed in the absorption layer 16 due to heat during exposure to EUV light is prevented. Specifically, the thermal expansion coefficient of the substrate 11 is preferably 0±1.0×10⁻⁷/° C. at 20° C., and more preferably 0±0.3×10⁻⁷/° C. at 20° C.

As a material having a small thermal expansion coefficient, for example, a SiO₂—TiO₂ glass or the like can be used. The SiO₂—TiO₂ glass is preferably a quartz glass containing 90 mass % to 95 mass % of SiO₂ and 5 mass % to 10 mass % of TiO₂. In the case where the content of TiO₂ is 5 mass % to 10 mass %, a linear expansion coefficient around room temperature is substantially zero, and a dimensional change around room temperature hardly occurs. The SiO₂—TiO₂ glass may contain trace components other than SiO₂ and TiO₂.

A first main surface 11a on which the Mo/Si multilayer reflection layer 12 of the substrate 11 is laminated preferably has high smoothness. The smoothness of the first main surface 11a can be evaluated by surface roughness obtained by performing measurement with an atomic force microscope. The surface roughness of the first main surface 11a is preferably 0.15 nm or less in terms of root mean square roughness Rq.

The first main surface 11a is preferably surface-processed so as to have a predetermined flatness. This is because a reflective mask provides a high pattern transfer accuracy and position accuracy. The substrate 11 has a flatness of preferably 100 nm or less, more preferably 50 nm or less, and still more preferably 30 nm or less, in a predetermined region (for example, a 132 mm×132 mm region) of the first main surface 11a.

The substrate 11 preferably has resistance to a cleaning solution used for cleaning a reflective mask blank, a reflective mask blank after pattern formation, and a reflective mask.

Further, the substrate 11 preferably has high rigidity in order to prevent deformation due to film stress of a layer (Mo/Si multilayer reflection layer 12 or the like) formed on or above the substrate 11. For example, the substrate 11 preferably has a high Young's modulus of 65 GPa or more.

A size, thickness, and the like of the substrate 11 are appropriately determined according to design values and the like of a reflective mask. The first main surface 11a of the substrate 11 is formed in a rectangular shape or a circular shape in plan view. In this specification, the rectangular shape includes, in addition to a long rectangular shape and a square, a shape in which a rounded corner is formed in a long rectangular shape or a square.

(Mo/Si Multilayer Reflection Layer)

The Mo/Si multilayer reflection layer 12 is formed by alternately laminating molybdenum (Mo) layer(s) and silicon (Si) layer(s).

The Mo/Si multilayer reflection layer 12 has a high reflectance for the EUV light. Specifically, in the case where the EUV light is incident on a surface of the Mo/Si multilayer reflection layer 12 at an incident angle of 6°, a maximum value of the reflectance for the EUV light in the vicinity of a wavelength of 13.5 nm is preferably 60% or more, and more preferably 65% or more. Further, in the case where the intermediate layer 13, the barrier layer 14, and the protective layer 15 are laminated on or above the Mo/Si multilayer reflection layer 12, similarly, a maximum value of the reflectance for the EUV light in the vicinity of the wavelength of 13.5 nm is preferably 60% or more, and more preferably 65% or more.

In the case where the Mo/Si multilayer reflection layer 12 has the maximum value of the reflectance for the EUV light in the vicinity of the wavelength of 13.5 nm of 60% or more, a Mo/Si multilayer reflection layer in which Mo layers and Si layers are alternately laminated for 30 to 60 cycles is preferably used.

Each layer constituting the Mo/Si multilayer reflection layer 12 can be formed to have a desired film thickness using a known film formation method such as a magnetron sputtering method or an ion beam sputtering method. For example, in the case where the Mo/Si multilayer reflection layer 12 is prepared using an ion beam sputtering method, for example, a Mo layer having a predetermined film thickness is formed using a Mo target. Thereafter, a Si layer having a predetermined film thickness is formed on or above the substrate 11. The Mo/Si multilayer reflection layer is formed by the lamination for 30 cycles to 60 cycles with the Mo layer and the Si layer as one cycle.

(Intermediate Layer)

The intermediate layer 13 prevents a decrease in reflectance for the EUV light due to the mixing on or above the Mo/Si multilayer reflection layer 12. That is, the decrease in reflectance for the EUV light due to the mixing of Si of an uppermost layer of the Mo/Si multilayer reflection layer 12 and a component element of the barrier layer 14 is prevented.

It is preferable that the intermediate layer 13 contain at least Si (silicon) and N (nitrogen). The intermediate layer 13 preferably contains 0.5 at % to 25 at % of N and 75 at % to 99.5 at % of Si, more preferably contains 0.5 at % to 15 at % of N and 85 at % to 99.5 at % of Si, still more preferably contains 0.5 at % to 10 at % of N and 90 at % to 99.5 at % of Si, yet still more preferably contains 1 at % to 9 at % of N and 91 at % to 99 at % of Si, even still more preferably contains 3 at % to 9 at % of N and 91 at % to 97 at % of Si, and particularly preferably contains 5 at % to 8 at % of N and 92 at % to 95 at % of Si.

It is preferable that the intermediate layer 13 have a film thickness of 0.1 nm to 2.4 nm from the viewpoint of preventing the decrease in reflectance for the EUV light due to the mixing on or above the Mo/Si multilayer reflection layer 12. The film thickness of the intermediate layer 13 is more preferably 0.4 nm or more, and still more preferably 0.8 nm or more. Further, the film thickness of the intermediate layer 13 is more preferably 1.5 nm or less, and still more preferably 1.3 nm or less.

The intermediate layer 13 can be formed by slightly nitriding a surface of the Si layer by exposing a surface of the Si layer, which is the uppermost layer of the Mo/Si multilayer reflection layer 12, to a nitrogen-containing atmosphere after the Mo/Si multilayer reflection layer 12 is formed. The nitrogen-containing atmosphere in the present specification means a nitrogen gas atmosphere or a mixed gas atmosphere of a nitrogen gas and an inert gas such as argon.

In the present embodiment, the nitrogen-containing atmosphere in which the surface of the Si layer is exposed is preferably such that a product of nitrogen partial pressure (Torr) and an exposure time (s) is 1×10⁻⁶ Torr·s (=1 langmuir (L)) or more. The product of the nitrogen partial pressure and the exposure time is an index indicating frequency at which nitrogen in the nitrogen-containing atmosphere collides with the surface of the Si layer, and hereinafter may be referred to as a “nitrogen exposure amount” in this specification. A value thereof is preferably 1×10⁻⁶ Torr·s or more, more preferably 1×10⁻³ Torr·s or more, still more preferably 1×10⁻² Torr·s or more, and yet still more preferably 1×10⁻¹ Torr·s or more in order to form the intermediate layer 13 by nitriding the surface of the Si layer.

As long as the nitrogen-containing atmosphere in which the surface of the Si layer is exposed satisfies the above conditions, a procedure for exposing the surface of the Si layer to the nitrogen-containing atmosphere is not particularly limited.

In the present embodiment, a temperature of the nitrogen-containing atmosphere in which the surface of the Si layer is exposed is preferably 0° C. to 150° C. In the case where the temperature of the nitrogen-containing atmosphere is 0° C. or higher, a problem due to adsorption of residual moisture in vacuum is less likely to occur. In the case where the temperature of the nitrogen-containing atmosphere is 150° C. or lower, excessive nitridation of the Si layer is prevented, and the decrease in reflectance for the EUV light can be prevented.

The temperature of the nitrogen-containing atmosphere is more preferably 10° C. to 140° C., and still more preferably 20° C. to 120° C.

(Barrier Layer)

The barrier layer 14 prevents hydrogen in an exposure machine from diffusing into the Mo/Si multilayer reflection layer 12 at the time of using the reflective mask to be described later. Accordingly, formation of a blister in the Mo/Si multilayer reflection layer 12 is prevented and protected. The barrier layer 14 is preferably made of a material having a low hydrogen diffusion coefficient. Specifically, at room temperature, the hydrogen diffusion coefficient is preferably 1×10⁻⁶ m²/s or less, and more preferably 1×10⁻⁷ m²/s or less.

The barrier layer 14 preferably has a refractive index (n) of 0.974 or less, and more preferably 0.957 or less in a wavelength band of the EUV light.

The barrier layer 14 preferably has an extinction coefficient (k) of 0.0351 or less in the wavelength band of the EUV light.

In the case where the refractive index (n) and the extinction coefficient (k) in the wavelength band of the EUV light fall within the above ranges, the barrier layer 14 has a good optical property with respect to the EUV light, and the decrease in reflectance for the EUV light is prevented.

A crystal state of the barrier layer 14 is preferably amorphous since smoothness of the surface of the barrier layer 14 is improved.

One aspect of the barrier layer 14 contains at least one element selected from the group consisting of tantalum (Ta) and niobium (Nb).

One aspect of the barrier layer 14 may further contain at least one element selected from the group consisting of ruthenium (Ru), rhodium (Rh), Si, Mo, and zirconium (Zr).

One aspect of the barrier layer 14 may further contain at least one element selected from the group consisting of nitrogen (N), oxygen (O), and boron (B).

Specific examples of one aspect of the barrier layer 14 include Ta, Nb, TaN, TaON, NbN, TaB₂, and NbB₂. All of these have the refractive index (n) of 0.957 or less in the wavelength band of the EUV light, and the extinction coefficient (k) of 0.0351 or less in the wavelength band of the EUV light.

Another aspect of the barrier layer 14 contains at least one selected from the group consisting of boron carbide (B₄C) and yttrium nitride (YN). B, C and Y have stability issues when used as single layers. For example, changing B, C, and Y into oxides may change the refractive index (n) and the extinction coefficient (k) in the wavelength band of the EUV light and cause the decrease in reflectance for the EUV light from the Mo/Si multilayer reflection layer 12, and thus B, C and Y cannot be used in the barrier layer 14. Since B₄C and YN have good stability, B₄C and YN do not cause the above problem when used as the barrier layer 14.

B₄C and YN both have the refractive index (n) of 0.974 or less in the wavelength band of the EUV light, and the extinction coefficient (k) of 0.0351 or less in the wavelength band of the EUV light.

In order to maintain the reflectance for the EUV light reflected by the Mo/Si multilayer reflection layer 12, the film thickness of the barrier layer 14 is preferably 2.5 nm or less, more preferably 2 nm or less, and still more preferably 1 nm or less. In order to prevent hydrogen in the exposure machine from diffusing into the Mo/Si multilayer reflection layer 12, the film thickness of the barrier layer 14 is preferably 0.5 nm or more.

As a method for forming the barrier layer 14, a known film forming method such as a magnetron sputtering method or an ion beam sputtering method can be used. The film thickness of the barrier layer can be measured using, for example, an XRR, a TEM, or the like.

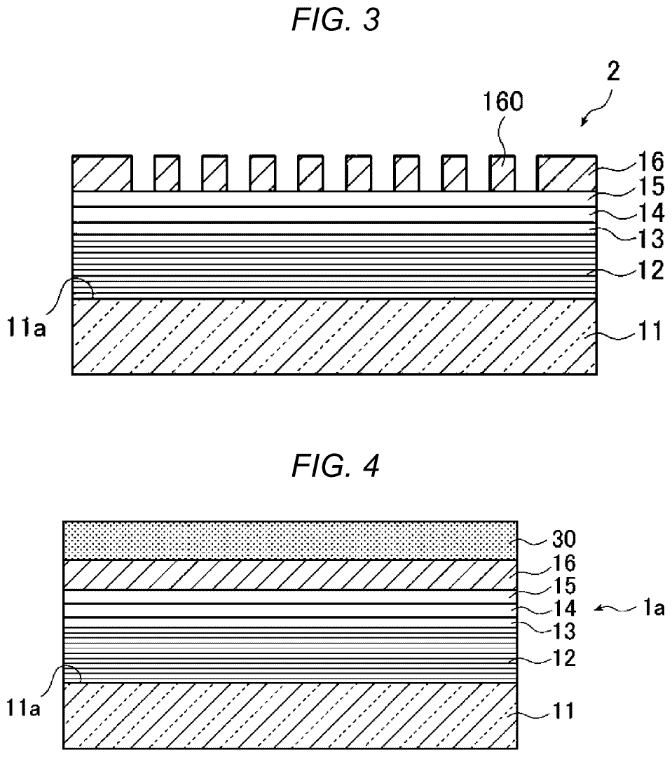

(Protective Layer) The protective layer 15 protects the Mo/Si multilayer reflection layer 12 by preventing the surface of the Mo/Si multilayer reflection layer 12 from being damaged by etching in the case where the absorption layer 16 is etched (usually dry-etched) to form an absorption layer pattern 160 (see FIG. 3) on the absorption layer 16 at the time of manufacturing the reflective mask 2 (see FIG. 3) to be described later. Further, in the case where a resist film (see FIG. 6) remaining on the reflective mask blank after the etching is removed by the cleaning solution and the reflective mask blank is cleaned, the Mo/Si multilayer reflection layer 12 is protected from the cleaning solution. Therefore, the obtained reflective mask 2 (see FIG. 3) has a good reflectance for the EUV light.

Although FIG. 1 shows a case in which the protective layer 15 is one layer, the protective layer 15 may have multiple layers.

As a material for forming the protective layer 15, a material that is hardly damaged by the etching in the case where the absorption layer 16 is etched is selected. The protective layer 15 preferably contains at least one element selected from the group consisting of Ru and Rh. For example, the protective layer 15 is made of Ru alone, a Ru alloy containing one or more metals selected from the group consisting of B, Si, titanium (Ti), Nb, Mo, zirconium (Zr), Y, lanthanum (La), cobalt (Co), Ta, Rh, and rhenium (Re) in Ru, a Ru material such as nitrides containing nitrogen in a Ru alloy, Rh alone, a Rh alloy containing one or more elements selected from the group consisting of B, Nb, Mo, Ta, iridium (Ir), palladium (Pd), Zr and Ti in Rh, or a Rh material such as nitrides containing N in a Rh alloy. Among these, Ru alone and the Ru alloy are preferred. Ru alone and the Ru alloy are particularly preferable since Ru alone and the Ru alloy are difficult to be etched by an oxygen-free gas and function as an etching stopper during processing of a reflective mask.

In the case where the protective layer 15 is formed of the Ru alloy, a Ru concentration in the Ru alloy is preferably 95 at % or more and less than 100 at %. In the case where the Ru concentration in the Ru alloy is within the above range, the protective layer 15 can have a function as an etching stopper when the absorption layer 16 is etched while ensuring a sufficient reflectance for the EUV light. Furthermore, cleaning resistance of the reflective mask can be ensured, and deterioration of the Mo/Si multilayer reflection layer 12 over time can be prevented.

A film thickness of the protective layer 15 is not particularly limited as long as the film thickness can ensure the function as the protective layer 15. In view of maintaining the reflectance for the EUV light reflected by the Mo/Si multilayer reflection layer 12, the film thickness of the protective layer 15 is preferably 1 nm or more, more preferably 1.5 nm or more, and still more preferably 2 nm or more. The film thickness of the protective layer 15 is preferably 10 nm or less, more preferably 8 nm or less, still more preferably 6 nm or less, and yet still more preferably 5 nm or less.

As a method for forming the protective layer 15, a known film forming method such as a magnetron sputtering method or an ion beam sputtering method can be used.

(Absorption Layer)

In order to use the absorption layer 16 in a reflective mask for EUV lithography, the absorption layer 16 is required to have properties such as a high absorption coefficient for the EUV light, be easily etched, and have a high cleaning resistance to the cleaning solution. The absorption layer 16 absorbs the EUV light and has an extremely low reflectance for the EUV light. Specifically, the maximum value of the reflectance for the EUV light in the vicinity of the wavelength of 13.5 nm in the case where a surface of the absorption layer 16 is irradiated with the EUV light is preferably 2% or less, and more preferably 1% or less. Therefore, the absorption layer 16 is required have a high absorption coefficient for the EUV light.

The absorption layer 16 is etched by dry-etching using a chlorine (Cl) gas such as Cl₂, SiCl₄, and CHCl₃ and a fluorine (F) gas such as CF₄ and CHF₃. Therefore, the absorption layer 16 is required to be easily etched.

Further, the absorption layer 16 is exposed to the cleaning solution in the case where a resist pattern 300 (see FIG. 6) remaining on the reflective mask blank after the etching is removed by the cleaning solution at the time of manufacturing the reflective mask 2 (see FIG. 3) to be described later. At this time, as the cleaning solution, sulfuric acid-hydrogen peroxide mixture (SPM), sulfuric acid, ammonia, ammonia-hydrogen peroxide mixture (APM), OH radical cleaning water, ozone water, and the like are used. In the EUV lithography, SPM is generally used as a resist cleaning solution.

SPM is a solution of sulfuric acid and hydrogen peroxide, for example, a solution of sulfuric acid and hydrogen peroxide mixed at a volume ratio of 3:1. At this time, a temperature of the SPM is preferably controlled to 100° C. or higher from the viewpoint of improving an etching rate. Therefore, the absorption layer 16 is required to have a high cleaning resistance to the cleaning solution. The absorption layer 16 preferably has a low etching rate (for example, 0.10 nm/min or less) when immersed in a solution of 75 vol % sulfuric acid and 25 vol % hydrogen peroxide at 100° C.

A crystal state of the absorption layer 16 is preferably amorphous. Accordingly, the absorption layer 16 can have an excellent smoothness and flatness. Further, since the smoothness and the flatness of the absorption layer 16 are improved, an edge roughness of the absorption layer pattern 160 (see FIG. 3) is reduced, and a dimensional accuracy of the absorption layer pattern 160 (see FIG. 3) can be increased.

The absorption layer 16 preferably contains one or more metals selected from the group consisting of Ta, Ti, tin (Sn), and Cr. Among the metals, Ta is more preferable. In addition to the metal, the absorption layer 16 may contain one or more components selected from the group consisting of O, N, B, hafnium (Hf), and hydrogen (H). Among these, it is preferable to contain one or more components selected from the group consisting of O, N, and B, and it is more preferable to contain N or B.

By containing N or B in the absorption layer 16, the crystal state of the absorption layer 16 can be made amorphous. Accordingly, the surface smoothness and the flatness of the absorption layer 16 are improved. Since the surface smoothness and the flatness of the absorption layer 16 are improved, the edge roughness of the absorption layer pattern 160 (see FIG. 3) is reduced, and the dimensional accuracy of the absorption layer pattern 160 (see FIG. 3) can be increased.

A film thickness of the absorption layer 16 is preferably 40 nm or less, for example, from the viewpoint of obtaining sufficient contrast while maintaining the reflectance of the absorption layer 16 at 1% or less. The film thickness of the absorption layer 16 is more preferably 35 nm or less, still more preferably 30 nm or less, yet still more preferably 25 nm or less, and even still more preferably 20 nm or less. The film thickness of the absorption layer 16 is determined by the reflectance, and the thinner the better.

The film thickness of the absorption layer 16 can be measured using, for example, an X-ray reflectance method (XRR) or a TEM. The absorption layer 16 can be formed by using the known film formation method such as a magnetron sputtering method and an ion beam sputtering method.

FIG. 2 is a schematic cross-sectional view showing another embodiment of a reflective mask blank of the present invention. A reflective mask blank 1b shown in FIG. 2 includes a substrate 11, a Mo/Si multilayer reflection layer 12 on the substrate 11, an intermediate layer 13 on the Mo/Si multilayer reflection layer 12, a barrier layer 14 on the intermediate layer 13, a protective layer 15 on the barrier layer 14, an absorption layer 16 on the protective layer 15, and an antireflection layer 17 on the absorption layer 16.

Among the components of the reflective mask blank 1b, the substrate 11, the Mo/Si multilayer reflection layer 12, the intermediate layer 13, the barrier layer 14, the protective layer 15, and the absorption layer 16 are the same as those of the above-mentioned reflective mask blank 1a, and therefore will be omitted.

(Antireflection Layer)

The antireflection layer 17 is formed on or above a main surface on an upper side (in a direction opposite to a protective layer 15 side) of the absorption layer 16. The antireflection layer 17 is formed of a layer having low reflection under an inspection light used for a mask pattern inspection. When preparing a reflective mask, a pattern is formed on the absorption layer, and then whether the pattern is formed as designed is inspected. In the mask pattern inspection, a light having a wavelength of about 190 nm to 260 nm is generally used as the inspection light. Since the antireflection layer 17 is provided on or above the absorption layer 16 under the inspection light used for the mask pattern inspection, the light reflectance at the wavelength of the inspection light is extremely low, and the contrast at the time of the inspection is improved.

In order to achieve the above characteristic, the antireflection layer 17 is made of a material having a lower refractive index at the wavelength of the inspection light than that of the absorption layer 16. The material for forming the antireflection layer 17 preferably contains one or more elements selected from the group consisting of Ta, Ru, Cr, Ti, and Si. These elements may be used alone or in combination of two or more kinds thereof.

Specific examples of the material for forming the antireflection layer 17 include Ta alone, Ru alone, Cr alone, Ti alone, Si alone, Ta nitride (TaN), Ru nitride (RuN), Cr nitride (CrN), Ti nitride (TiN), Si nitride (Si₃N₄), Ta boride (TaB₂), Ru boride (RuB), Cr boride (CrB), Ti boride (TiB), Si boride (SiB), and Ta boron nitride (TaBN). These may be used alone or in combination of two or more kinds thereof.

If a film thickness of the antireflection layer 17 is too thick, it takes time to etching the antireflection layer 17. Furthermore, shadowing and the like may become large. On the other hand, if the antireflection layer 17 is too thin, the function as the antireflection layer 17 may not be stably and sufficiently performed.

Therefore, from the viewpoint of preventing a thickness of a pattern of the reflective mask blank 1b, the film thickness of the antireflection layer 17 may be approximately several nanometers, and preferably 10 nm or less. The film thickness of the antireflection layer 17 is more preferably 8 nm or less, still more preferably 6 nm or less, yet still more preferably 5 nm or less, and even still more preferably 4 nm. The film thickness of the antireflection layer 17 is more preferably 0.5 nm or more, still more preferably 1 nm or more, yet still more preferably 1.5 nm or more, and even still more preferably 2 nm or more. The film thickness of the antireflection layer 17 can be measured using, for example, an XRR, a TEM, or the like.

The reflective mask blanks 1a and 1b according to the present embodiment may include a known functional film in the field of the reflective mask blank, in addition to the Mo/Si multilayer reflection layer 12, the intermediate layer 13, the barrier layer 14, the protective layer 15, the absorption layer 16, and the antireflection layer 17.

Specific examples of such a functional film include a high dielectric coating to be applied to a back surface side of a substrate in order to promote electrostatic chucking of the substrate, as described in JP2003-501823A. Here, the back surface of the substrate refers to a surface of the substrate 11 opposite to a first main surface 11a in FIG. 1.

For the high dielectric coating applied to the back surface of the substrate for such a purpose, an electrical conductivity and a thickness of a constituent material are selected such that a sheet resistance is 100 Ω/square or less. The constituent material of the high dielectric coating can be widely selected from those described in known documents. For example, a coating having a high dielectric constant, specifically, a coating made of Si, TiN, Mo, Cr, or TaSi, as described in JP2003-501823A, can be applied. A thickness of the high dielectric coating may be, for example, 10 nm to 1,000 nm.

The high dielectric coating can be formed by a known film formation method, for example, a sputtering method such as a magnetron sputtering method or an ion beam sputtering method, a CVD method, a vacuum deposition method, or an electrolytic plating method.

A method for manufacturing a reflective mask blank according to the present embodiment includes the following steps (a) to (e):
a) step of forming a Mo/Si multilayer reflection layer on or above a substrate;
B) step of forming an intermediate layer on or above the Mo/Si multilayer reflection layer formed in the step a);
c) step of forming a barrier layer on or above the intermediate layer formed in the step b);
d) step of forming a protective layer on or above the barrier layer formed in the step c); and
e) step of forming an absorption layer on or above the protective layer formed in the step d).

According to the method for manufacturing a reflective mask blank according to the present embodiment, the reflective mask blank 1a shown in FIG. 1 is obtained.

In the method for manufacturing a reflective mask blank according the present embodiment, it is preferable that the Mo/Si multilayer reflection layer, the barrier layer, and the protective layer be formed by the sputtering method, and the step of forming the Mo/Si multilayer reflection layer (step a), the step of forming the intermediate layer (step b), the step of forming the barrier layer (step c), and the step of forming the protective layer (d) be continuously performed in the same film forming chamber.

By performing the above procedure, after the Mo/Si multilayer reflection layer is formed, the intermediate layer can be formed by exposing the surface of the Si layer, which is the uppermost layer of the Mo/Si multilayer reflection layer, to a nitrogen-containing atmosphere and slightly nitriding the surface of the Si layer, and after the intermediate layer is formed, the barrier layer and the protective layer can be formed without exposure to an external environment.

FIG. 3 is a schematic cross-sectional view showing an embodiment of a reflective mask of the present invention.

In the reflective mask 2 shown in FIG. 3, the pattern (absorption layer pattern) 160 is formed in the absorption layer 16 of the reflective mask blank 1a shown in FIG. 1. That is, the reflective mask 2 includes the substrate 11, the Mo/Si multilayer reflection layer 12 on the substrate 11, the intermediate layer 13 on the Mo/Si multilayer reflection layer 12, the barrier layer 14 on the intermediate layer 13, the protective layer 15 on the barrier layer 14, and the absorption layer 16 on the protective layer 15, and the pattern (absorption layer pattern) 160 is formed in the absorption layer 16.

Among the components of the reflective mask 2, the substrate 11, the Mo/Si multilayer reflection layer 12, the intermediate layer 13, the barrier layer 14, the protective layer 15, and the absorption layer 16 are the same as those of the above-mentioned reflective mask blank 1a.

In the method for manufacturing a reflective mask according to the present embodiment, the absorption layer 16 of the reflective mask blank 1a manufactured by the method for manufacturing a reflective mask blank according to the present embodiment is patterned to form the pattern (absorption layer pattern) 160.

A procedure for forming the pattern in the absorption layer 16 of the reflective mask blank 1a will be described with reference to the drawings.

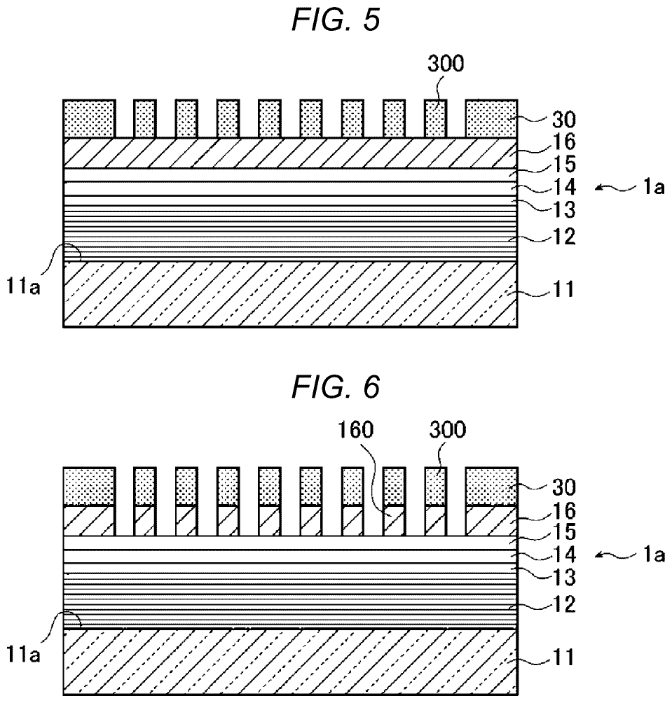

As shown in FIG. 4, the resist film 30 is formed on the absorption layer 16 of the reflective mask blank 1a. Next, as shown in FIG. 5, the resist pattern 300 is formed on the resist film 30 using an electron beam lithography machine. Next, as shown in FIG. 6, the absorption layer pattern 160 is formed in the absorption layer 16 using the resist film 30 on which the resist pattern 300 is formed as a mask. Next, by removing the resist film 30 by a cleaning solution including an acid or a base, the reflective mask 2 in which the absorption layer pattern 160 is exposed is obtained.

Most of the resist pattern 300 and the resist film 30 are removed in a process of forming the absorption layer pattern 160, and in order to remove the remaining resist pattern 300 and resist film 30, cleaning is performed using the cleaning solution including the acid or the base.

### EXAMPLES

The present invention will be illustrated in more detail using Examples 1 to 6 below, but the present invention is not limited thereto.

(Preparation of Hydrogen Irradiation Test Sample)

### Example 1

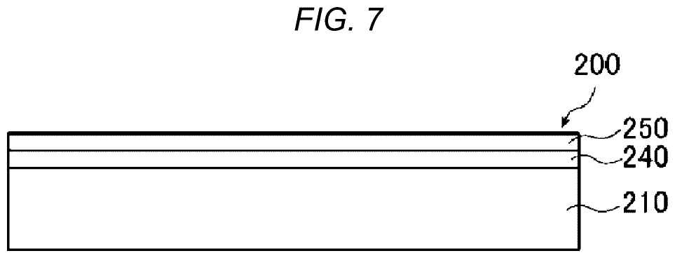

In Example 1, a Si wafer substrate 210 (outer shape: 4 inches, thickness: 0.5 mm, resistance value: 1 Ωcm to 100 Ωcm, alignment surface 100) was used as a substrate for film formation. A Ta layer having a film thickness of 5 nm was formed on a surface of the Si wafer substrate 210 by a magnetron sputtering method to form a barrier layer 240. Next, a Ru layer having a film thickness of 2.5 nm was formed on the barrier layer 240 by the magnetron sputtering method to form a protective layer 250, thereby preparing a hydrogen irradiation test sample 200 shown in FIG. 7.

### Example 2

A TaON layer having a film thickness of 2.5 nm was formed as the barrier layer 240 on the surface of the Si wafer substrate 210 by the same method as above, and then a Ru layer having a film thickness of 2.5 nm was formed on the barrier layer 240 by the magnetron sputtering method to form the protective layer 250, thereby preparing a hydrogen irradiation test sample 200 in Example 2.

The film thicknesses of the barrier layer 240 and the protective layer 250 in each of Examples 1 and 2 were measured by an XRR using an X-ray diffractometer (SmartLab HTP, manufactured by Rigaku Corporation). Further, from an X-ray diffraction (XRD) measurement result by the same device, it was found that a crystal state of the barrier layer 240 in each of Examples 1 and 2 was amorphous.

(Hydrogen Irradiation Test)

In a hydrogen irradiation test, a test piece obtained by cutting the hydrogen irradiation test sample 200 into 2.5 cm squares was attached to a Si dummy substrate, set in a hydrogen irradiation test device simulating an EUV exposure device, and irradiated with hydrogen (including hydrogen ions).

(Observation of Sample Surface after Hydrogen Irradiation)

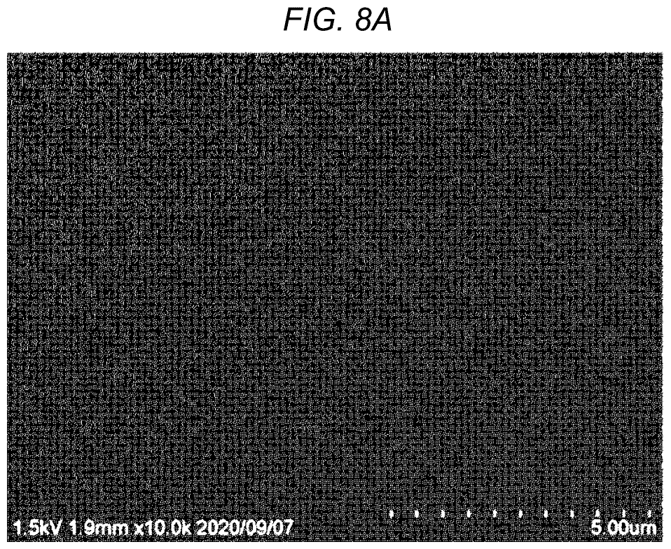

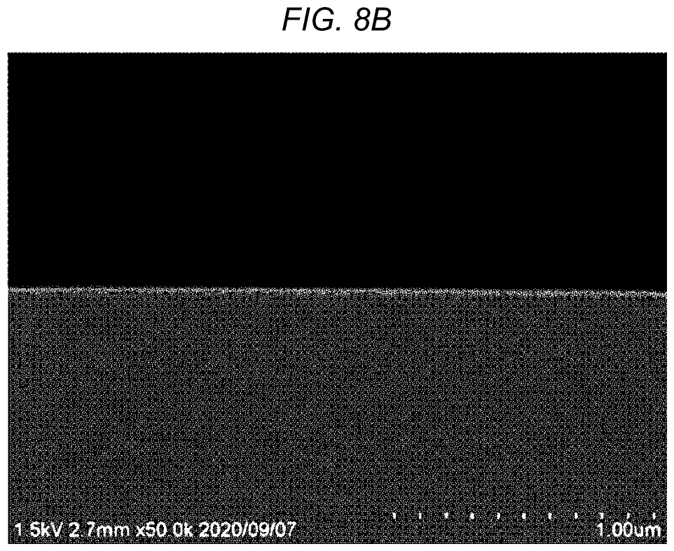

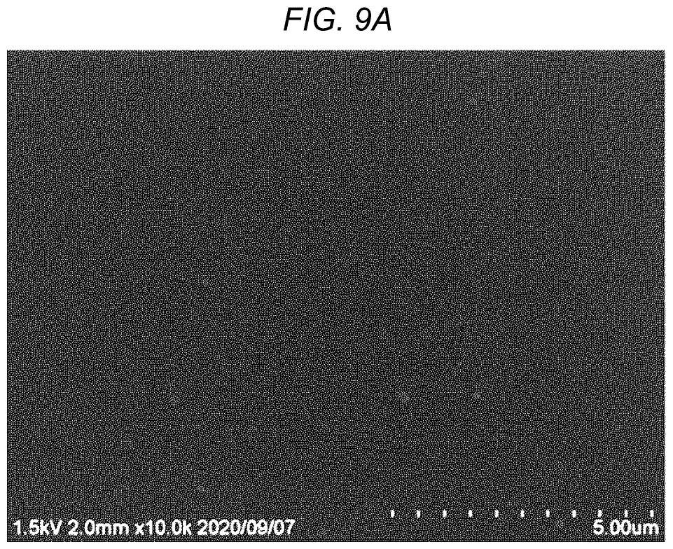

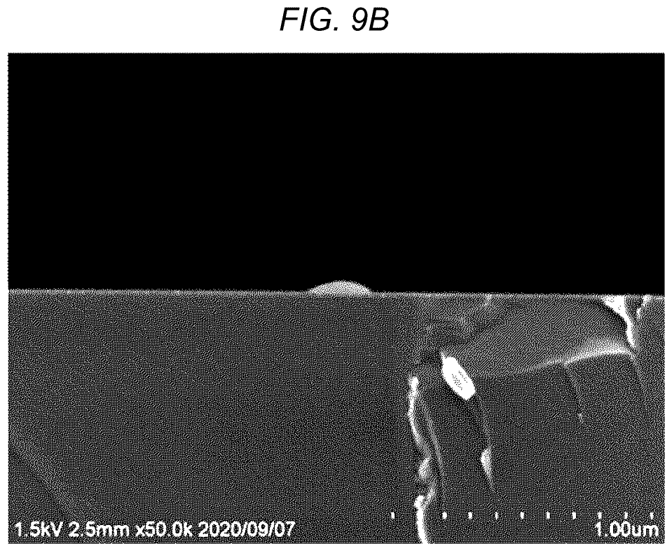

The test piece after the hydrogen irradiation was observed using a scanning electron microscope (SU-70, manufactured by Hitachi High-Tech Corporation). FIGS. 8A and 8B show observation images by a scanning electron microscope of a test sample in Example 1 after hydrogen irradiation. FIG. 8A is an observation image of a sample surface, and FIG. 8B is an observation image of a sample cross section. FIGS. 9A and 9B show observation images observed by a scanning electron microscope of a test sample in Example 2 after hydrogen irradiation. FIG. 9A is an observation image of a sample surface, and FIG. 9B is an observation image of a sample cross section.

As shown in FIG. 8A, it was observed that the blister was not expressed in the field of view of 12.7 μm×9.5 μm on a sample surface of the Ta layer of the barrier layer 240. As shown in FIG. 9A, on a sample surface of the TaON layer of the barrier layer 240, acceptable slight blisters having an occurrence density of about 0.066/μm² were observed within the above field of view. The number of the generated blisters was counted using an image analysis software (WinRoof, manufactured by MITANI CORPORATION) of scanning electron microscope images.

In the above-described hydrogen irradiation test, the presence or absence of formation of a blister was observed on the hydrogen irradiation test sample 200 including the Si wafer substrate 210, the barrier layer 240, and the protective layer 250, but in the reflective mask blank 1a shown in FIG. 1, it is considered that similar results can be obtained in the case where the uppermost layer of the Mo/Si multilayer reflection layer 12 is the Si layer, and the barrier layer 14 and the protective layer 15 have the same composition as the barrier layer 240 and the protective layer 250. That is, it is considered that the formation of the blister can be prevented by using the Ta layer or the TaON layer as the barrier layer 14.

(Analysis by Diffusion Simulation after Hydrogen Irradiation)

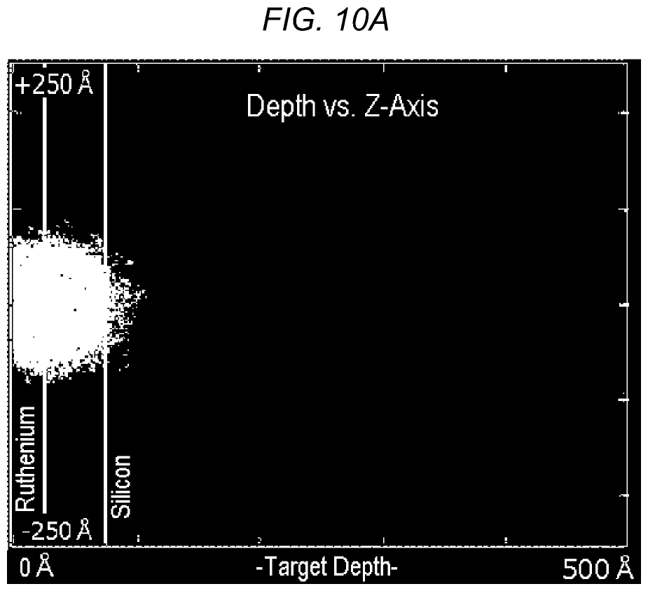

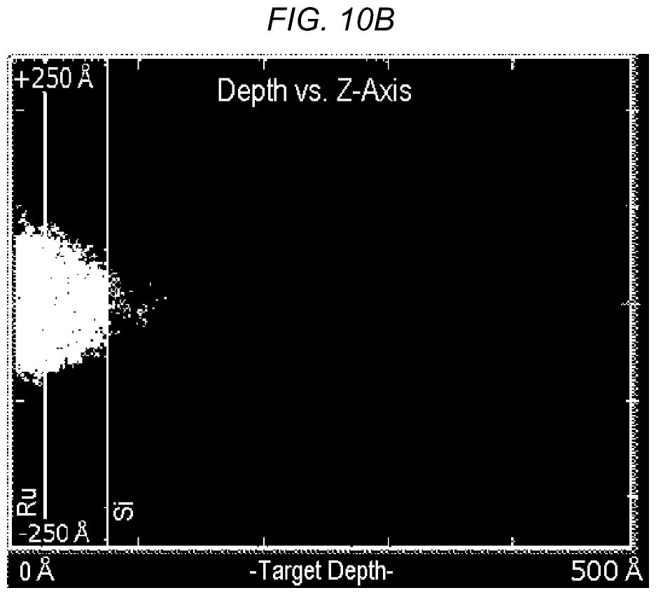

The hydrogen irradiation test sample 200 in each of Examples 1 and 2 prepared in the above procedure was subjected to an ion diffusion simulation after the hydrogen irradiation. Ta and TaON are selected as a material of the barrier layer 240, and sample film compositions, a film thickness of each layer, and ion energy were all the same as in the hydrogen irradiation test, analysis results of a hydrogen ion concentration in the sample are shown in FIGS. 10A and 10B. FIG. 10A is a result of the sample in Example 1, and FIG. 10B is a result of the sample in Example 2.

It was found that Ta and TaON, which have a small hydrogen diffusion coefficient, significantly prevent hydrogen diffusion into the Si substrate. On the other hand, in the blister formation occurring at an interface between the barrier layer 240 and the protective layer 250, it is suggested that a large amount of hydrogen is distributed in any barrier layer 240. In the case where the barrier layer 240 is the Ta layer, stability of a hydride is low and it is difficult to form a hydrogen compound, so it is thought that the blisters do not occur. In selecting a barrier layer material that prevents blistering, key points are a hydrogen diffusion barrier property and difficulty in forming a highly volatile hydrogen compound.

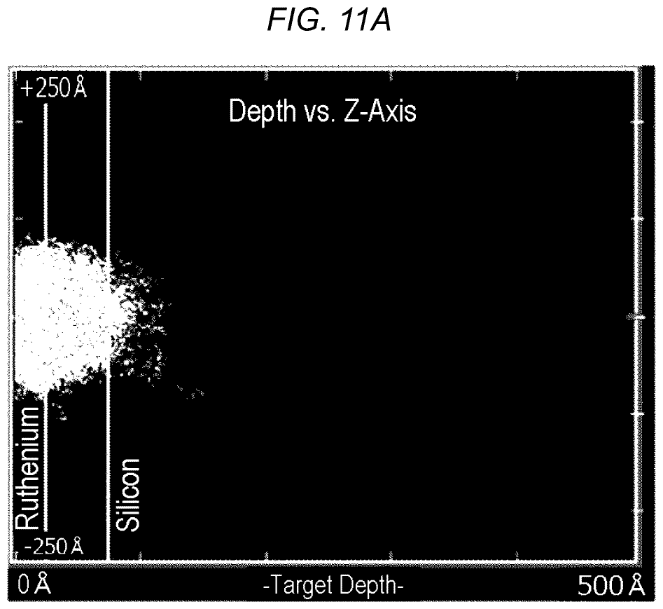

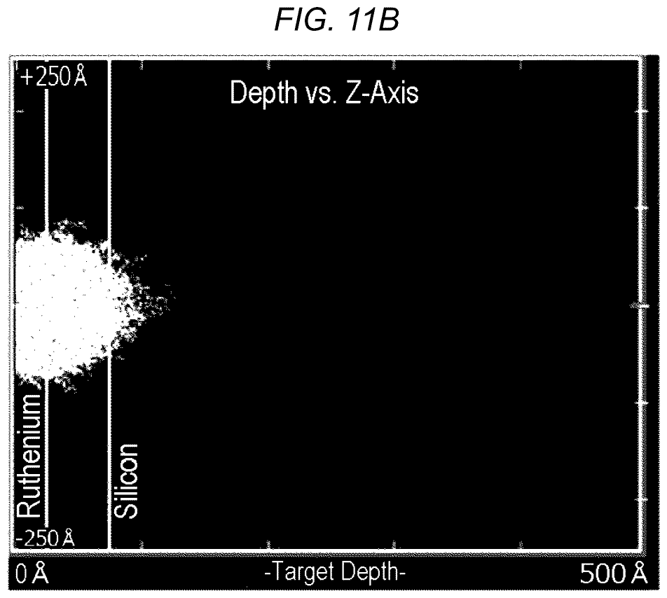

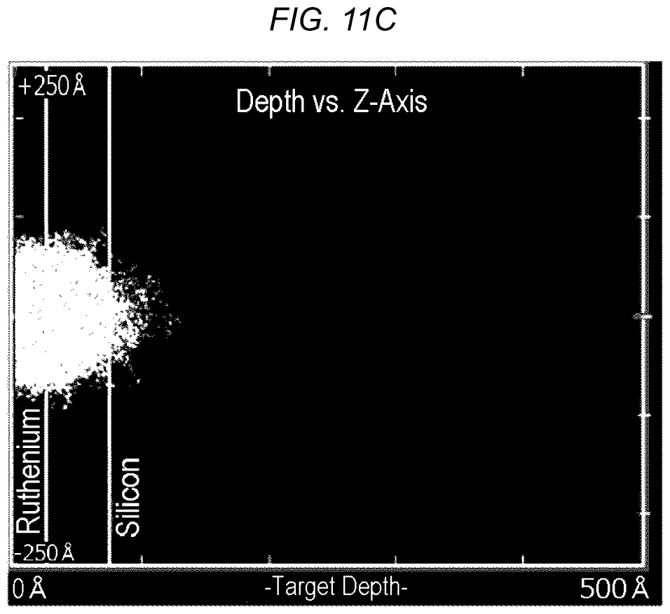

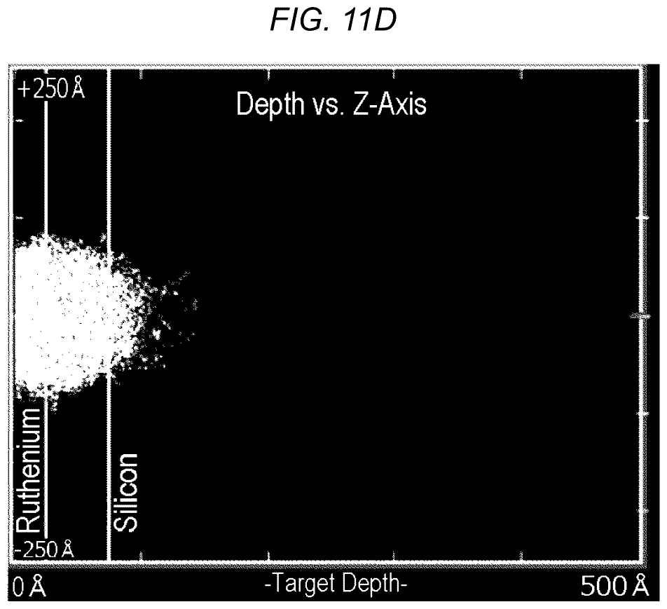

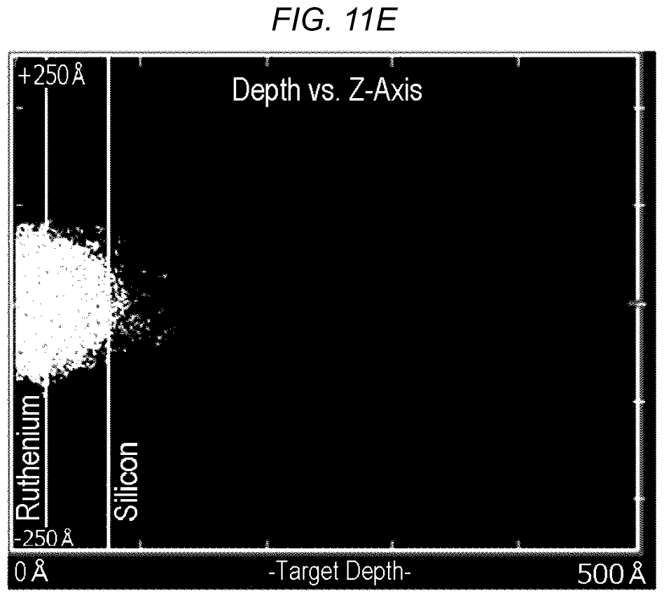

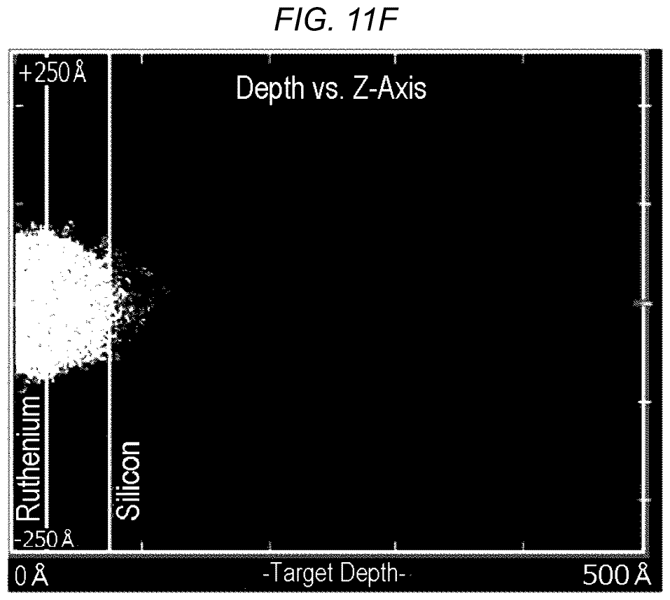

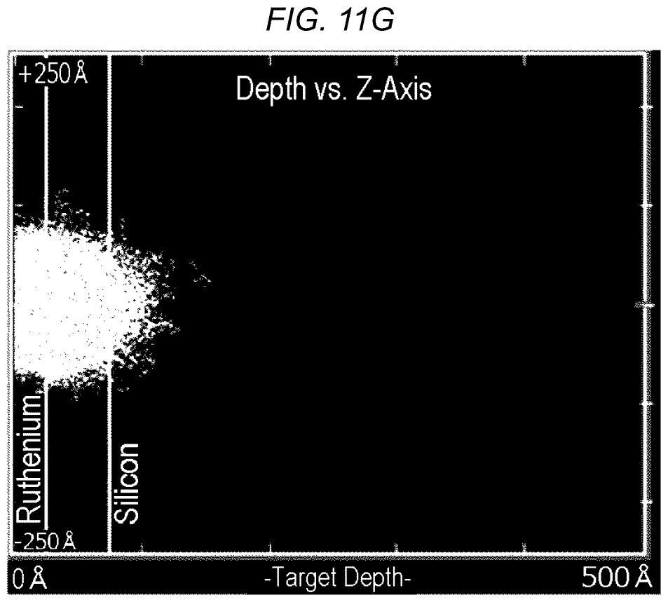

FIGS. 11A to 11G show results of simulating the hydrogen diffusion barrier property in the case where various materials that are difficult to form the highly volatile hydrogen compound are used for the barrier layer 240. FIG. 11A shows a result in the case where the barrier layer 240 is a B₄C layer having a film thickness of 2.5 nm, FIG. 11B shows a result in the case where the barrier layer 240 is a TaN layer having a film thickness of 2.5 nm, FIG. 11C shows a result in the case where the barrier layer 240 is a TaB₂ layer having a film thickness of 2.5 nm, FIG. 11D shows a result in the case where the barrier layer 240 is a Nb layer having a film thickness of 2.5 nm, FIG. 11E shows a result in the case where the barrier layer 240 is a NbN layer having a film thickness of 2.5 nm, FIG. 11F shows a result in the case where the barrier layer 240 is a NbB₂ layer having a film thickness of 2.5 nm, and FIG. 11G shows a result in the case where the barrier layer 240 is a YN layer having a film thickness of 2.5 nm. From these results, the B₄C layer, the TaN layer, the TaB₂ layer, the Nb layer, the NbN layer, the NbB₂ layer, and the YN layer have a high hydrogen diffusion barrier property and are suitable as materials for the barrier layer of the reflective mask blank according to the present embodiment.

### Examples 3 and 4

Based on the results of simulating the hydrogen diffusion barrier property, a Nb layer having a film thickness of 5 nm was formed as the barrier layer 240 on the surface of the Si wafer substrate 210 by the same method as Examples 1 and 2, and then a Ru layer having a film thickness of 2.5 nm was formed on the barrier layer 240 by the magnetron sputtering method to form the protective layer 250, thereby preparing a hydrogen irradiation test sample 200 in Example 3. Further, the film thickness of the Nb layer was set to 2.5 nm to prepare a hydrogen irradiation test sample 200 in Example 4.

### Examples 5 and 6

The barrier layer 240 was not formed on the surface of the Si wafer substrate 210, and a RuTa layer having a film thickness of 2.5 nm was formed by the magnetron sputtering method to form the protective layer 250, thereby preparing a hydrogen irradiation test sample 200 in Example 5. Further, the barrier layer 240 was not formed on the surface of the Si wafer substrate 210, and a RuNb layer having a film thickness of 2.5 nm was formed by the magnetron sputtering method to form the protective layer 250, thereby preparing a hydrogen irradiation test sample 200 in Example 6.

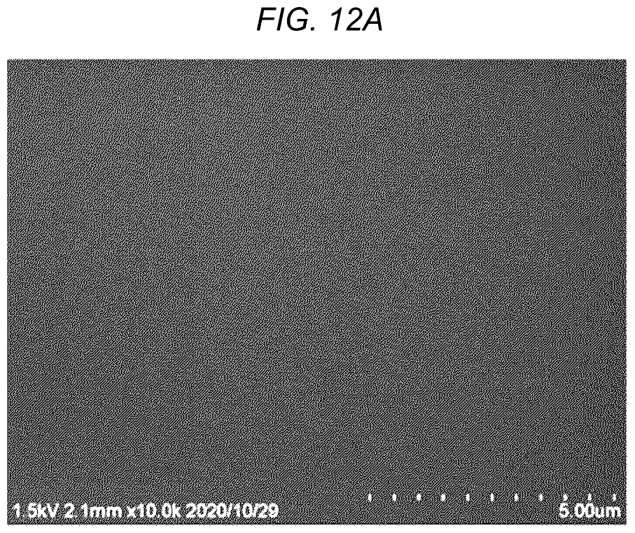

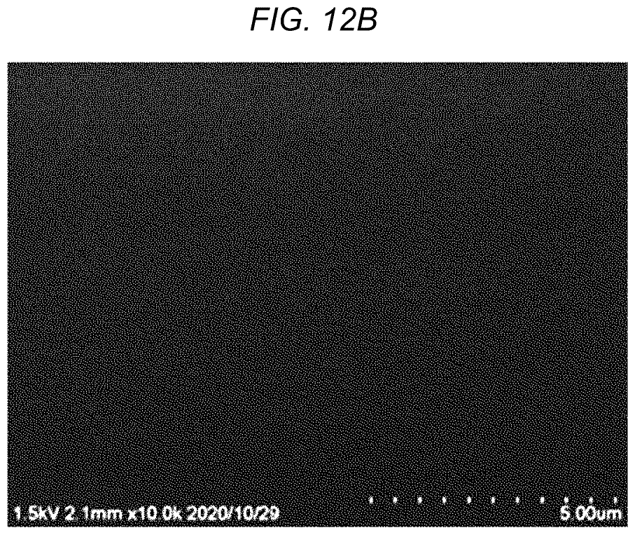

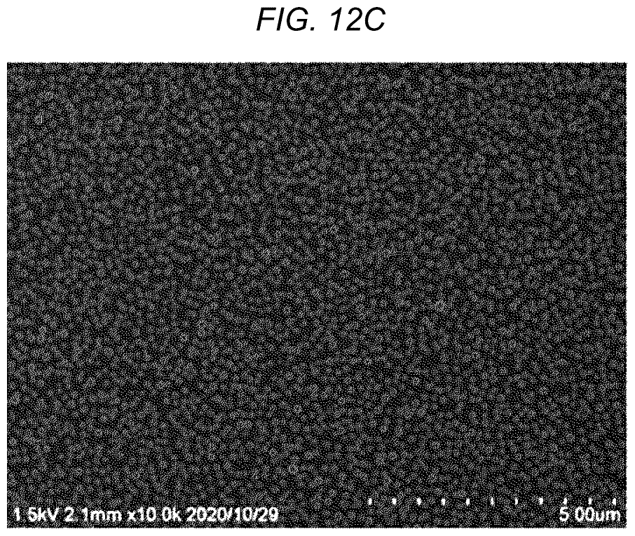

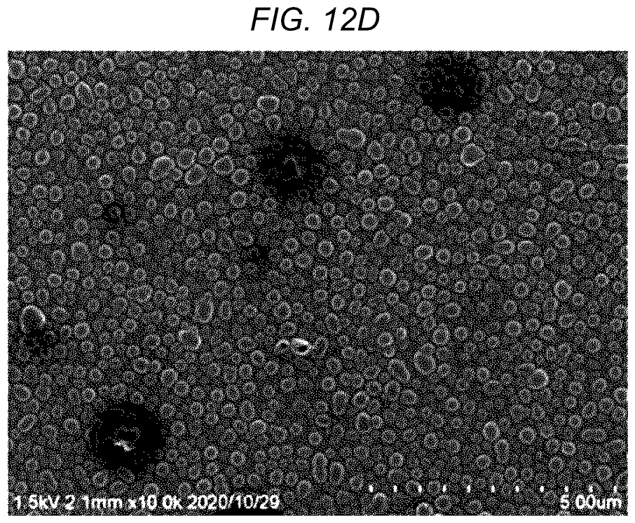

Using the hydrogen irradiation test samples 200 in Examples 3 to 6, hydrogen irradiation tests were performed in the same manner as in Examples 1 and 2, and sample surfaces after the hydrogen irradiation were observed. FIG. 12A is an observation image of the sample surface in Example 3, FIG. 12B is an observation image of the sample surface in Example 4, FIG. 12C is an observation image of the sample surface in Example 5, and FIG. 12D is an observation image of the sample surface in Example 6.

As shown in FIGS. 12A and 12B, it was observed that no blisters were observed within the field of view of 12.7 μm×9.5 μm on the surface of the sample in which the Nb layer having the film thickness of 5 nm or 2.5 nm was formed as the barrier layer 240.

As shown in FIGS. 12C and 12D, blisters having an occurrence density of about 50.8/μm² and about 27.0/μm² in the field of view were respectively observed on the surface of the sample in which the barrier layer 240 was not formed but the RuTa layer having the film thickness of 2.5 nm was formed and on the surface of the sample in which the barrier layer 240 was not formed but the RuNb layer having the film thickness of 2.5 nm was formed. From these results, it is considered that the formation of the blisters cannot be prevented even in the case where the RuTa layer and the RuNb layer are formed as the protective layer 15 without forming the barrier layer.

When the samples in Examples 5 and 6 were analyzed using an X-ray photoelectron spectrometer (XPS), a Ta average concentration in the RuTa layer of the sample in Example 5 was 11.1 at %, and a Ta average concentration in the RuNb layer of the sample in Example 6 was 18.0 at %.

(Occurrence of Mixing)

Regarding the hydrogen irradiation test samples 200 in Examples 1, 3, and 4, occurrence of mixing between Si of the Si wafer substrate 210 and a component element of the barrier layer 240 was found. In Example 1, fitting was performed using a film material (composition) and a film thickness as parameters from a waveform in an X-ray reflectance measurement method (XRR), and it was found that a TaSi layer having a film thickness of 0.87 nm was formed at the interface between Si of the Si wafer substrate 210 and the Ta layer of the barrier layer 240. In Examples 3 and 4, using the same procedure, it was found that a NbSi layer having a film thickness of 0.42 nm in Example 3 and 0.21 nm in Example 4 was formed at an interface between Si of the Si wafer substrate 210 and the Nb layer of the barrier layer 240.

### Example 7

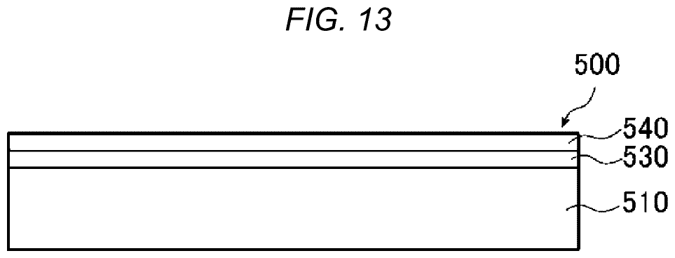

In this example, a sample 500 shown in FIG. 13 was prepared. Specifically, a SiN layer having a film thickness of 20 nm was formed on a surface of the same Si wafer substrate 510 as in Example 1 using the magnetron sputtering method to form an intermediate layer 530. Next, a Ta layer having a film thickness of 10 nm was formed on the intermediate layer 530 by the magnetron sputtering method to form a barrier layer 540. For this sample 500, the fitting was performed using a film material (composition) and a film thickness as parameters from a waveform in an X-ray reflectance measurement method (XRR).

As a result, no layer was formed at an interface between Si of the Si wafer substrate 510 and the SiN layer of the intermediate layer 530 and at an interface between the SiN layer of the intermediate layer 530 and the Ta layer of the barrier layer 540. This result indicates that mixing of Si of the Si wafer substrate 510 and a component element of the intermediate layer 530 and mixing of the component element of the intermediate layer 530 and a component element of the barrier layer 540 did not occur.

(Decrease in Reflectance for EUV Light Due to Mixing)

For a reflective mask blank having the following configuration, a peak reflectance of the EUV light was evaluated by simulation.

(Model 1)

Substrate: Si substrate, thickness 0.5 mm

Mo/Si multilayer reflection layer: 40 pairs of Mo layer having film thickness of 2.3 nm and Si layer having film thickness of 4.5 nm which are laminated

Mixing layer: TaSi layer, film thickness 0.8 nm

Barrier layer: Ta layer, film thickness 2.5 nm

Protective layer: Ru layer, film thickness 2.5 nm

(Model 2)

Substrate: Si substrate, thickness 0.5 mm

Mo/Si multilayer reflection layer: 40 pairs of Mo layer having film thickness of 2.3 nm and Si layer having film thickness of 4.5 nm which are laminated

Intermediate layer: SiN layer, film thickness 0.8 nm

Barrier layer: Ta layer, film thickness 2.5 nm

Protective layer: Ru layer, film thickness 2.5 nm

Model 1 assumes that the mixing layer (TaSi layer) is formed at an interface between the Si layer of the Mo/Si multilayer reflection layer and the Ta layer as the barrier layer. Model 2 assumes that mixing of Si in the Mo/Si multilayer reflection layer and Ta in the barrier layer is prevented by providing the SiN layer as the intermediate layer.

For both, the peak reflectance for the EUV light was evaluated by the simulation in the case where the EUV light was incident at an incident angle of 6°, and a decrease in the peak reflectance of 0.756% was found in Model 1 compared to Model 2.

(Model 3)

Substrate: Si substrate, thickness 0.5 mm

Mo/Si multilayer reflection layer: 40 pairs of Mo layer having film thickness of 2.3 nm and Si layer having film thickness of 4.5 nm which are laminated

Mixing layer: TaSi layer, film thickness 0.8 nm

Barrier layer: Ta layer, film thickness 2.0 nm

Protective layer: Ru layer, film thickness 2.5 nm

(Model 4)

Substrate: Si substrate, thickness 0.5 mm

Mo/Si multilayer reflection layer: 40 pairs of Mo layer having film thickness of 2.3 nm and Si layer having film thickness of 4.5 nm which are laminated

Intermediate layer: SiN layer, film thickness 0.8 nm

Barrier layer: Ta layer, film thickness 2.0 nm

Protective layer: Ru layer, film thickness 2.5 nm

Model 3 assumes that the mixing layer (TaSi layer) is formed at an interface between the Si layer of the Mo/Si multilayer reflection layer and the Ta layer as the barrier layer. Model 4 assumes that mixing of Si in the Mo/Si multilayer reflection layer and Ta in the barrier layer is prevented by providing the SiN layer as the intermediate layer.

For both, the peak reflectance for the EUV light was evaluated by the simulation in the case where the EUV light was incident at an incident angle of 6°, and a decrease in the peak reflectance of 0.712% was found in Model 3 compared to Model 4.

(Model 5)

Substrate: Si substrate, thickness 0.5 mm

Mo/Si multilayer reflection layer: 40 pairs of Mo layer having film thickness of 2.3 nm and Si layer having film thickness of 4.5 nm which are laminated

Mixing layer: TaSi layer, film thickness 0.8 nm

Barrier layer: Ta layer, film thickness 1.5 nm

Protective layer: Ru layer, film thickness 2.5 nm

(Model 6)

Substrate: Si substrate, thickness 0.5 mm

Mo/Si multilayer reflection layer: 40 pairs of Mo layer having film thickness of 2.3 nm and Si layer having film thickness of 4.5 nm which are laminated

Intermediate layer: SiN layer, film thickness 0.8 nm

Barrier layer: Ta layer, film thickness 1.5 nm

Protective layer: Ru layer, film thickness 2.5 nm

Model 5 assumes that the mixing layer (TaSi layer) is formed at an interface between the Si layer of the Mo/Si multilayer reflection layer and the Ta layer as the barrier layer. Model 6 assumes that mixing of Si in the Mo/Si multilayer reflection layer and Ta in the barrier layer is prevented by providing the SiN layer as the intermediate layer.

For both, the peak reflectance for the EUV light was evaluated by the simulation in the case where the EUV light was incident at an incident angle of 6°, and a decrease in the peak reflectance of 0.661% was found in Model 5 compared to Model 6.

(Model 7)

Substrate: Si substrate, thickness 0.5 mm

Mo/Si multilayer reflection layer: 40 pairs of Mo layer having film thickness of 2.3 nm and Si layer having film thickness of 4.5 nm which are laminated

Mixing layer: TaSi layer, film thickness 0.8 nm

Barrier layer: Ta layer, film thickness 1.0 nm

Protective layer: Ru layer, film thickness 2.5 nm

(Model 8)

Substrate: Si substrate, thickness 0.5 mm

Mo/Si multilayer reflection layer: 40 pairs of Mo layer having film thickness of 2.3 nm and Si layer having film thickness of 4.5 nm which are laminated

Intermediate layer: SiN layer, film thickness 0.8 nm

Barrier layer: Ta layer, film thickness 1.0 nm

Protective layer: Ru layer, film thickness 2.5 nm

Model 7 assumes that the mixing layer (TaSi layer) is formed at an interface between the Si layer of the Mo/Si multilayer reflection layer and the Ta layer as the barrier layer. Model 8 assumes that mixing of Si in the Mo/Si multilayer reflection layer and Ta in the barrier layer is prevented by providing the SiN layer as the intermediate layer.

For both, the peak reflectance for the EUV light was evaluated by the simulation in the case where the EUV light was incident at an incident angle of 6°, and a decrease in the peak reflectance of 0.628% was found in Model 7 compared to Model 8.

(Model 9)

Substrate: Si substrate, thickness 0.5 mm

Mo/Si multilayer reflection layer: 40 pairs of Mo layer having film thickness of 2.3 nm and Si layer having film thickness of 4.5 nm which are laminated

Mixing layer: TaSi layer, film thickness 0.8 nm

Barrier layer: Ta layer, film thickness 0.5 nm

Protective layer: Ru layer, film thickness 2.5 nm

(Model 10)

Substrate: Si substrate, thickness 0.5 mm

Mo/Si multilayer reflection layer: 40 pairs of Mo layer having film thickness of 2.3 nm and Si layer having film thickness of 4.5 nm which are laminated

Intermediate layer: SiN layer, film thickness 0.8 nm

Barrier layer: Ta layer, film thickness 0.5 nm

Protective layer: Ru layer, film thickness 2.5 nm

Model 9 assumes that the mixing layer (TaSi layer) is formed at an interface between the Si layer of the Mo/Si multilayer reflection layer and the Ta layer as the barrier layer. Model assumes that mixing of Si in the Mo/Si multilayer reflection layer and Ta in the barrier layer is prevented by providing the SiN layer as the intermediate layer.

For both, the peak reflectance for the EUV light was evaluated by the simulation in the case where the EUV light was incident at an incident angle of 6°, and a decrease in the peak reflectance of 0.600% was found in Model 9 compared to Model 10.

(Model 11)

Substrate: Si substrate, thickness 0.5 mm

Mo/Si multilayer reflection layer: 40 pairs of Mo layer having film thickness of 2.3 nm and Si layer having film thickness of 4.5 nm which are laminated

Mixing layer: TaSi layer, film thickness 1.3 nm

Barrier layer: Ta layer, film thickness 2.5 nm

Protective layer: Ru layer, film thickness 2.5 nm

(Model 12)

Substrate: Si substrate, thickness 0.5 mm

Mo/Si multilayer reflection layer: 40 pairs of Mo layer having film thickness of 2.3 nm and Si layer having film thickness of 4.5 nm which are laminated

Intermediate layer: SiN layer, film thickness 1.3 nm

Barrier layer: Ta layer, film thickness 2.5 nm

Protective layer: Ru layer, film thickness 2.5 nm

Model 11 assumes that the mixing layer (TaSi layer) is formed at an interface between the Si layer of the Mo/Si multilayer reflection layer and the Ta layer as the barrier layer. Model 12 assumes that mixing of Si in the Mo/Si multilayer reflection layer and Ta in the barrier layer is prevented by providing the SiN layer as the intermediate layer.

For both, the peak reflectance for the EUV light was evaluated by the simulation in the case where the EUV light was incident at an incident angle of 6°, and a decrease in the peak reflectance of 1.529% was found in Model 11 compared to Model 12.

(Model 13)

Substrate: Si substrate, thickness 0.5 mm

Mo/Si multilayer reflection layer: 40 pairs of Mo layer having film thickness of 2.3 nm and Si layer having film thickness of 4.5 nm which are laminated

Mixing layer: TaSi layer, film thickness 1.3 nm

Barrier layer: Ta layer, film thickness 2.0 nm

Protective layer: Ru layer, film thickness 2.5 nm

(Model 14)

Substrate: Si substrate, thickness 0.5 mm

Mo/Si multilayer reflection layer: 40 pairs of Mo layer having film thickness of 2.3 nm and Si layer having film thickness of 4.5 nm which are laminated

Intermediate layer: SiN layer, film thickness 1.3 nm

Barrier layer: Ta layer, film thickness 2.0 nm

Protective layer: Ru layer, film thickness 2.5 nm

Model 13 assumes that the mixing layer (TaSi layer) is formed at an interface between the Si layer of the Mo/Si multilayer reflection layer and the Ta layer as the barrier layer. Model 14 assumes that mixing of Si in the Mo/Si multilayer reflection layer and Ta in the barrier layer is prevented by providing the SiN layer as the intermediate layer.

For both, the peak reflectance for the EUV light was evaluated by the simulation in the case where the EUV light was incident at an incident angle of 6°, and a decrease in the peak reflectance of 1.464% was found in Model 13 compared to Model 14.

(Model 15)

Substrate: Si substrate, thickness 0.5 mm

Mo/Si multilayer reflection layer: 40 pairs of Mo layer having film thickness of 2.3 nm and Si layer having film thickness of 4.5 nm which are laminated

Mixing layer: TaSi layer, film thickness 1.3 nm

Barrier layer: Ta layer, film thickness 1.5 nm

Protective layer: Ru layer, film thickness 2.5 nm

(Model 16)

Substrate: Si substrate, thickness 0.5 mm

Mo/Si multilayer reflection layer: 40 pairs of Mo layer having film thickness of 2.3 nm and Si layer having film thickness of 4.5 nm which are laminated

Intermediate layer: SiN layer, film thickness 1.3 nm

Barrier layer: Ta layer, film thickness 1.5 nm

Protective layer: Ru layer, film thickness 2.5 nm

Model 15 assumes that the mixing layer (TaSi layer) is formed at an interface between the Si layer of the Mo/Si multilayer reflection layer and the Ta layer as the barrier layer. Model 16 assumes that mixing of Si in the Mo/Si multilayer reflection layer and Ta in the barrier layer is prevented by providing the SiN layer as the intermediate layer.

For both, the peak reflectance for the EUV light was evaluated by the simulation in the case where the EUV light was incident at an incident angle of 6°, and a decrease in the peak reflectance of 1.396% was found in Model 15 compared to Model 16.

(Model 17)

Substrate: Si substrate, thickness 0.5 mm

Mo/Si multilayer reflection layer: 40 pairs of Mo layer having film thickness of 2.3 nm and Si layer having film thickness of 4.5 nm which are laminated

Mixing layer: TaSi layer, film thickness 1.3 nm

Barrier layer: Ta layer, film thickness 1.0 nm

Protective layer: Ru layer, film thickness 2.5 nm

(Model 18)

Substrate: Si substrate, thickness 0.5 mm

Mo/Si multilayer reflection layer: 40 pairs of Mo layer having film thickness of 2.3 nm and Si layer having film thickness of 4.5 nm which are laminated

Intermediate layer: SiN layer, film thickness 1.3 nm

Barrier layer: Ta layer, film thickness 1.0 nm

Protective layer: Ru layer, film thickness 2.5 nm

Model 17 assumes that the mixing layer (TaSi layer) is formed at an interface between the Si layer of the Mo/Si multilayer reflection layer and the Ta layer as the barrier layer. Model 18 assumes that mixing of Si in the Mo/Si multilayer reflection layer and Ta in the barrier layer is prevented by providing the SiN layer as the intermediate layer.

For both, the peak reflectance for the EUV light was evaluated by the simulation in the case where the EUV light was incident at an incident angle of 6°, and a decrease in the peak reflectance of 1.348% was found in Model 17 compared to Model 18.

(Model 19)

Substrate: Si substrate, thickness 0.5 mm

Mo/Si multilayer reflection layer: 40 pairs of Mo layer having film thickness of 2.3 nm and Si layer having film thickness of 4.5 nm which are laminated

Mixing layer: TaSi layer, film thickness 1.3 nm

Barrier layer: Ta layer, film thickness 0.5 nm

Protective layer: Ru layer, film thickness 2.5 nm

(Model 20)

Substrate: Si substrate, thickness 0.5 mm

Mo/Si multilayer reflection layer: 40 pairs of Mo layer having film thickness of 2.3 nm and Si layer having film thickness of 4.5 nm which are laminated

Intermediate layer: SiN layer, film thickness 1.3 nm

Barrier layer: Ta layer, film thickness 0.5 nm

Protective layer: Ru layer, film thickness 2.5 nm

Model 19 assumes that the mixing layer (TaSi layer) is formed at an interface between the Si layer of the Mo/Si multilayer reflection layer and the Ta layer as the barrier layer. Model assumes that mixing of Si in the Mo/Si multilayer reflection layer and Ta in the barrier layer is prevented by providing the SiN layer as the intermediate layer.

For both, the peak reflectance for the EUV light was evaluated by the simulation in the case where the EUV light was incident at an incident angle of 6°, and a decrease in the peak reflectance of 1.303% was found in Model 19 compared to Model 20.

(Model 21)

Substrate: Si substrate, thickness 0.5 mm

Mo/Si multilayer reflection layer: 40 pairs of Mo layer having film thickness of 2.3 nm and Si layer having film thickness of 4.5 nm which are laminated

Mixing layer: NbSi layer, film thickness 0.8 nm

Barrier layer: Nb layer, film thickness 2.5 nm

Protective layer: Ru layer, film thickness 2.5 nm

(Model 22)

Substrate: Si substrate, thickness 0.5 mm

Mo/Si multilayer reflection layer: 40 pairs of Mo layer having film thickness of 2.3 nm and Si layer having film thickness of 4.5 nm which are laminated

Intermediate layer: SiN layer, film thickness 0.8 nm

Barrier layer: Nb layer, film thickness 2.5 nm

Protective layer: Ru layer, film thickness 2.5 nm

Model 21 assumes that the mixing layer (NbSi layer) is formed at an interface between the Si layer of the Mo/Si multilayer reflection layer and the Nb layer as the barrier layer Model 22 assumes that mixing of Si in the Mo/Si multilayer reflection layer and Nb in the barrier layer is prevented by providing the SiN layer as the intermediate layer.

For both, the peak reflectance for the EUV light was evaluated by the simulation in the case where the EUV light was incident at an incident angle of 6°, and a decrease in the peak reflectance of 0.058% was found in Model 21 compared to Model 22.

(Model 23)

Substrate: Si substrate, thickness 0.5 mm

Mo/Si multilayer reflection layer: 40 pairs of Mo layer having film thickness of 2.3 nm and Si layer having film thickness of 4.5 nm which are laminated

Mixing layer: NbSi layer, film thickness 0.8 nm

Barrier layer: Nb layer, film thickness 2.0 nm

Protective layer: Ru layer, film thickness 2.5 nm

(Model 24)

Substrate: Si substrate, thickness 0.5 mm

Mo/Si multilayer reflection layer: 40 pairs of Mo layer having film thickness of 2.3 nm and Si layer having film thickness of 4.5 nm which are laminated

Intermediate layer: SiN layer, film thickness 0.8 nm

Barrier layer: Nb layer, film thickness 2.0 nm

Protective layer: Ru layer, film thickness 2.5 nm

Model 23 assumes that the mixing layer (NbSi layer) is formed at an interface between the Si layer of the Mo/Si multilayer reflection layer and the Nb layer as the barrier layer. Model 24 assumes that mixing of Si in the Mo/Si multilayer reflection layer and Nb in the barrier layer is prevented by providing the SiN layer as the intermediate layer.

For both, the peak reflectance for the EUV light was evaluated by the simulation in the case where the EUV light was incident at an incident angle of 6°, and a decrease in the peak reflectance of 0.073% was found in Model 23 compared to Model 24.

(Model 25)

Substrate: Si substrate, thickness 0.5 mm

Mo/Si multilayer reflection layer: 40 pairs of Mo layer having film thickness of 2.3 nm and Si layer having film thickness of 4.5 nm which are laminated

Mixing layer: NbSi layer, film thickness 0.8 nm

Barrier layer: Nb layer, film thickness 1.5 nm

Protective layer: Ru layer, film thickness 2.5 nm

(Model 26)

Substrate: Si substrate, thickness 0.5 mm

Mo/Si multilayer reflection layer: 40 pairs of Mo layer having film thickness of 2.3 nm and Si layer having film thickness of 4.5 nm which are laminated

Intermediate layer: SiN layer, film thickness 0.8 nm

Barrier layer: Nb layer, film thickness 1.5 nm

Protective layer: Ru layer, film thickness 2.5 nm

Model 25 assumes that the mixing layer (NbSi layer) is formed at an interface between the Si layer of the Mo/Si multilayer reflection layer and the Nb layer as the barrier layer. Model 26 assumes that mixing of Si in the Mo/Si multilayer reflection layer and Nb in the barrier layer is prevented by providing the SiN layer as the intermediate layer.

For both, the peak reflectance for the EUV light was evaluated by the simulation in the case where the EUV light was incident at an incident angle of 6°, and a decrease in the peak reflectance of 0.091% was found in Model 25 compared to Model 26.

(Model 27)

Substrate: Si substrate, thickness 0.5 mm

Mo/Si multilayer reflection layer: 40 pairs of Mo layer having film thickness of 2.3 nm and Si layer having film thickness of 4.5 nm which are laminated

Mixing layer: NbSi layer, film thickness 0.8 nm

Barrier layer: Nb layer, film thickness 1.0 nm

Protective layer: Ru layer, film thickness 2.5 nm

(Model 28)

Substrate: Si substrate, thickness 0.5 mm

Mo/Si multilayer reflection layer: 40 pairs of Mo layer having film thickness of 2.3

nm and Si layer having film thickness of 4.5 nm which are laminated

Intermediate layer: SiN layer, film thickness 0.8 nm

Barrier layer: Nb layer, film thickness 1.0 nm

Protective layer: Ru layer, film thickness 2.5 nm

Model 27 assumes that the mixing layer (NbSi layer) is formed at an interface between the Si layer of the Mo/Si multilayer reflection layer and the Nb layer as the barrier layer. Model 28 assumes that mixing of Si in the Mo/Si multilayer reflection layer and Nb in the barrier layer is prevented by providing the SiN layer as the intermediate layer.

For both, the peak reflectance for the EUV light was evaluated by the simulation in the case where the EUV light was incident at an incident angle of 6°, and a decrease in the peak reflectance of 0.108% was found in Model 27 compared to Model 28.

(Model 29)

Substrate: Si substrate, thickness 0.5 mm

Mo/Si multilayer reflection layer: 40 pairs of Mo layer having film thickness of 2.3 nm and Si layer having film thickness of 4.5 nm which are laminated

Mixing layer: NbSi layer, film thickness 0.8 nm

Barrier layer: Nb layer, film thickness 0.5 nm

Protective layer: Ru layer, film thickness 2.5 nm

(Model 30)

Substrate: Si substrate, thickness 0.5 mm

Mo/Si multilayer reflection layer: 40 pairs of Mo layer having film thickness of 2.3 nm and Si layer having film thickness of 4.5 nm which are laminated

Intermediate layer: SiN layer, film thickness 0.8 nm

Barrier layer: Nb layer, film thickness 0.5 nm

Protective layer: Ru layer, film thickness 2.5 nm

Model 29 assumes that the mixing layer (NbSi layer) is formed at an interface between the Si layer of the Mo/Si multilayer reflection layer and the Nb layer as the barrier layer. Model 30 assumes that mixing of Si in the Mo/Si multilayer reflection layer and Nb in the barrier layer is prevented by providing the SiN layer as the intermediate layer.

For both, the peak reflectance for the EUV light was evaluated by the simulation in the case where the EUV light was incident at an incident angle of 6°, and a decrease in the peak reflectance of 0.126% was found in Model 29 compared to Model 30.

(Model 31)

Substrate: Si substrate, thickness 0.5 mm

Mo/Si multilayer reflection layer: 40 pairs of Mo layer having film thickness of 2.3 nm and Si layer having film thickness of 4.5 nm which are laminated

Mixing layer: NbSi layer, film thickness 1.3 nm

Barrier layer: Nb layer, film thickness 2.5 nm

Protective layer: Ru layer, film thickness 2.5 nm

(Model 32)

Substrate: Si substrate, thickness 0.5 mm

Mo/Si multilayer reflection layer: 40 pairs of Mo layer having film thickness of 2.3 nm and Si layer having film thickness of 4.5 nm which are laminated

Intermediate layer: SiN layer, film thickness 1.3 nm

Barrier layer: Nb layer, film thickness 2.5 nm

Protective layer: Ru layer, film thickness 2.5 nm

Model 31 assumes that the mixing layer (NbSi layer) is formed at an interface between the Si layer of the Mo/Si multilayer reflection layer and the Nb layer as the barrier layer. Model 32 assumes that mixing of Si in the Mo/Si multilayer reflection layer and Nb in the barrier layer is prevented by providing the SiN layer as the intermediate layer.

For both, the peak reflectance for the EUV light was evaluated by the simulation in the case where the EUV light was incident at an incident angle of 6°, and a decrease in the peak reflectance of 0.024% was found in Model 31 compared to Model 32.

(Model 33)

Substrate: Si substrate, thickness 0.5 mm

Mo/Si multilayer reflection layer: 40 pairs of Mo layer having film thickness of 2.3 nm and Si layer having film thickness of 4.5 nm which are laminated

Mixing layer: NbSi layer, film thickness 1.3 nm

Barrier layer: Nb layer, film thickness 2.0 nm

Protective layer: Ru layer, film thickness 2.5 nm

(Model 34)

Substrate: Si substrate, thickness 0.5 mm

Mo/Si multilayer reflection layer: 40 pairs of Mo layer having film thickness of 2.3 nm and Si layer having film thickness of 4.5 nm which are laminated

Intermediate layer: SiN layer, film thickness 1.3 nm

Barrier layer: Nb layer, film thickness 2.0 nm

Protective layer: Ru layer, film thickness 2.5 nm

Model 33 assumes that the mixing layer (NbSi layer) is formed at an interface between the Si layer of the Mo/Si multilayer reflection layer and the Nb layer as the barrier layer. Model 34 assumes that mixing of Si in the Mo/Si multilayer reflection layer and Nb in the barrier layer is prevented by providing the SiN layer as the intermediate layer.

For both, the peak reflectance for the EUV light was evaluated by the simulation in the case where the EUV light was incident at an incident angle of 6°, and a decrease in the peak reflectance of 0.053% was found in Model 33 compared to Model 34.

(Model 35)

Substrate: Si substrate, thickness 0.5 mm

Mo/Si multilayer reflection layer: 40 pairs of Mo layer having film thickness of 2.3 nm and Si layer having film thickness of 4.5 nm which are laminated

Mixing layer: NbSi layer, film thickness 1.3 nm

Barrier layer: Nb layer, film thickness 1.5 nm

Protective layer: Ru layer, film thickness 2.5 nm

(Model 36)

Substrate: Si substrate, thickness 0.5 mm

Mo/Si multilayer reflection layer: 40 pairs of Mo layer having film thickness of 2.3 nm and Si layer having film thickness of 4.5 nm which are laminated

Intermediate layer: SiN layer, film thickness 1.3 nm

Barrier layer: Nb layer, film thickness 1.5 nm

Protective layer: Ru layer, film thickness 2.5 nm

Model 35 assumes that the mixing layer (NbSi layer) is formed at an interface between the Si layer of the Mo/Si multilayer reflection layer and the Nb layer as the barrier layer. Model 36 assumes that mixing of Si in the Mo/Si multilayer reflection layer and Nb in the barrier layer is prevented by providing the SiN layer as the intermediate layer.

For both, the peak reflectance for the EUV light was evaluated by the simulation in the case where the EUV light was incident at an incident angle of 6°, and a decrease in the peak reflectance of 0.093% was found in Model 35 compared to Model 36.

(Model 37)

Substrate: Si substrate, thickness 0.5 mm

Mo/Si multilayer reflection layer: 40 pairs of Mo layer having film thickness of 2.3 nm and Si layer having film thickness of 4.5 nm which are laminated

Mixing layer: NbSi layer, film thickness 1.3 nm

Barrier layer: Nb layer, film thickness 1.0 nm

Protective layer: Ru layer, film thickness 2.5 nm

(Model 38)

Substrate: Si substrate, thickness 0.5 mm

Mo/Si multilayer reflection layer: 40 pairs of Mo layer having film thickness of 2.3 nm and Si layer having film thickness of 4.5 nm which are laminated

Intermediate layer: SiN layer, film thickness 1.3 nm

Barrier layer: Nb layer, film thickness 1.0 nm

Protective layer: Ru layer, film thickness 2.5 nm

Model 37 assumes that the mixing layer (NbSi layer) is formed at an interface between the Si layer of the Mo/Si multilayer reflection layer and the Nb layer as the barrier layer. Model 38 assumes that mixing of Si in the Mo/Si multilayer reflection layer and Nb in the barrier layer is prevented by providing the SiN layer as the intermediate layer.

For both, the peak reflectance for the EUV light was evaluated by the simulation in the case where the EUV light was incident at an incident angle of 6°, and a decrease in the peak reflectance of 0.128% was found in Model 37 compared to Model 38.

(Model 39)

Substrate: Si substrate, thickness 0.5 mm

Mo/Si multilayer reflection layer: 40 pairs of Mo layer having film thickness of 2.3 nm and Si layer having film thickness of 4.5 nm which are laminated

Mixing layer: NbSi layer, film thickness 1.3 nm

Barrier layer: Nb layer, film thickness 0.5 nm

Protective layer: Ru layer, film thickness 2.5 nm

(Model 40)

Substrate: Si substrate, thickness 0.5 mm

Mo/Si multilayer reflection layer: 40 pairs of Mo layer having film thickness of 2.3 nm and Si layer having film thickness of 4.5 nm which are laminated

Intermediate layer: SiN layer, film thickness 1.3 nm

Barrier layer: Nb layer, film thickness 0.5 nm

Protective layer: Ru layer, film thickness 2.5 nm

Model 39 assumes that the mixing layer (NbSi layer) is formed at an interface between the Si layer of the Mo/Si multilayer reflection layer and the Nb layer as the barrier layer. Model 40 assumes that mixing of Si in the Mo/Si multilayer reflection layer and Nb in the barrier layer is prevented by providing the SiN layer as the intermediate layer.

For both, the peak reflectance for the EUV light was evaluated by the simulation in the case where the EUV light was incident at an incident angle of 6°, and a decrease in the peak reflectance of 0.169% was found in Model 39 compared to Model 40.

Although the present invention has been described in detail with reference to specific embodiments, it is apparent to those skilled in the art that various changes and modifications can be made without departing from the spirit and scope of the present invention. The present application is based on Japanese Patent Application (No. 2021-114867) filed on Jul. 12, 2021, and Japanese Patent Application (No. 2022-000942) filed on Jan. 6, 2022, and the contents of which are incorporated herein by reference.

### REFERENCE SIGNS LIST

1a, 1b: reflective mask blank
2: reflective mask
11: substrate
12: Mo/Si multilayer reflection layer
13: intermediate layer
14: barrier layer
15: protective layer
16: absorption layer
17: antireflection layer
30: resist film
160: absorption layer pattern
200: hydrogen irradiation test sample
210: Si wafer substrate
240: barrier layer
250: protective layer
300: resist pattern
500: sample
510: Si wafer substrate
530: intermediate layer
540: barrier layer

What is claimed is:

1. A reflective mask blank comprising:
a substrate;
a Mo/Si multilayer reflection layer formed by alternately laminating a molybdenum (Mo) layer and a silicon (Si) layer on or above the substrate;
an intermediate layer on or above the Mo/Si multilayer reflection layer;
a barrier layer on or above the intermediate layer;
a protective layer on or above the barrier layer; and
an absorption layer on or above the protective layer.

2. The reflective mask blank according to claim 1, wherein the barrier layer comprises at least one element selected from the group consisting of tantalum (Ta) and niobium (Nb).

3. The reflective mask blank according to claim 2, wherein the barrier layer further comprises at least one element selected from the group consisting of ruthenium (Ru), rhodium (Rh), Si, Mo, and zirconium (Zr).

4. The reflective mask blank according to claim 2, wherein the barrier layer further comprises at least one element selected from the group consisting of nitrogen (N), oxygen (O), and boron (B).

5. The reflective mask blank according to claim 1, wherein the barrier layer comprises at least one selected from the group consisting of boron carbide (B₄C) and yttrium nitride (YN).

6. The reflective mask blank according to claim 1, wherein the intermediate layer comprises at least silicon (Si) and nitrogen (N).

7. The reflective mask blank according to claim 6, wherein the intermediate layer comprises 75 at % to 99.5 at % of Si and 0.5 at % to 25 at % of N.

8. The reflective mask blank according to claim 1, wherein the protective layer comprises at least one element selected from the group consisting of Ru and Rh.

9. The reflective mask blank according to claim 1, wherein the barrier layer has a film thickness of 0.5 nm to 2.5 nm.

10. The reflective mask blank according to claim 1, wherein the intermediate layer has a film thickness of 0.1 nm to 2.4 nm.

11. The reflective mask blank according to claim 1, wherein the protective layer has a film thickness of 1 nm to 10 nm.

12. The reflective mask blank according to claim 1, further comprising, on or above the absorption layer, an antireflection layer with respect to an inspection light used for a mask pattern inspection.

13. A method for manufacturing the reflective mask blank according to claim 1, the method comprising:
forming the Mo/Si multilayer reflection layer on or above the substrate;
forming the intermediate layer on or above the Mo/Si multilayer reflection layer;
forming the barrier layer on or above the intermediate layer;
forming the protective layer on or above the barrier layer; and
forming the absorption layer on or above the protective layer.

14. The method according to claim 13, wherein the Mo/Si multilayer reflection layer, the barrier layer, and the protective layer are formed by a sputtering method, and
the steps of forming the Mo/Si multilayer reflection layer, forming the intermediate layer, forming the barrier layer, and forming the protective layer are continuously performed in a same film forming chamber.
